(19) United States
(12) Patent Application Publication
(10) Pub. No.: US 2004/0062402 A1
(43) Pub. Date: Apr. 1, 2004

(54) Audio reproduction apparatus

(75) Inventors: Shinichi Fujita, Hamamatsu-shi (JP); Hironari Kawai, Hamamatsu-shi (JP)

Correspondence Address: Pillsbury Winthrop LLP, Intellectual Property Group, Suite 2800, 725 South Figueroa Street, Los Angeles, CA, 90017-5406, US

(73) Assignee: Yamaha Corporation, Hamamatsu-shi (JP)

(21) Appl. No.: 10/621,910

(22) Filed: Jul. 17, 2003

(30) Foreign Application Priority Data
Jul. 19, 2002 (JP) 2002-210528
Jul. 24, 2002 (JP) 2002-215588

(51) Int. Cl. H04R 5/00; H03G 3/00; H02B 1/00

(52) U.S. Cl. 381/18; 381/19; 381/307; 381/104; 381/109; 381/123

(57) ABSTRACT

In a first mode where no audio reproduction is to be executed in a second zone, each selector switch shifts to a Z1 contact. In a second mode where audio reproduction is to be executed in the second zone, each selector switch shifts to a Z2 contact. In the second mode, a DSP executes sound field correction on main and rear signals such that sound fields in the first zone have desired characteristics. Setting section can select either a first speaker mode where speakers connected to first output terminals and speakers connected to second output terminals are both positioned in the first zone, or a second speaker mode where the speakers connected to the first output terminals are positioned in the first zone and the speakers connected to the second output terminals are positioned in the second zone. When the output to the first output terminals is off while the output to the second output terminals is on in the second speaker mode, the DSP stops outputting the surround signals.

### BACKGROUND OF THE INVENTION

The present invention relates generally to audio reproduction apparatus having a multichannel audio reproduction function, and more particularly to an improved audio reproduction apparatus which can switch a portion of multichannel power amplifiers provided for a first zone to one or more power amplifiers for a second zone. The present invention also relates to an improved audio reproduction apparatus with the multichannel audio reproduction function which can perform ON/OFF control on output to two groups of speaker output terminals independently of each other.

As a form multichannel audio reproduction system, there have been popularly employed, in recent years, digital surround systems which use audio compression techniques, such as Dolby (registered trademark) Digital, DTS (registered trademark: an acronym for Digital Theater System) and AAC (Advanced Audio Coding) techniques.

Recently, multizone audio reproduction systems have also began into wide use, which are designed to deliver audio signals to a plurality of rooms. Heretofore, in cases where a single audio reproduction apparatus, having the multichannel audio reproduction function, is used to perform ON/OFF control on delivery of audio signals to two zones independently of each other, it has been necessary to secure in advance a portion (one or more but not all) of multichannel power amplifiers provided for a first zone (hereinafter also called “first-zone multichannel power amplifiers”) for use as one or more multichannel power amplifiers for a second zone (hereinafter also called “second-zone multichannel power amplifiers”). Hereinafter, delivery of audio signals to the second zone different from the first zone will be referred to as “Zone-2 audio reproduction”.

FIG. 18 is a block diagram illustrating a setup of a conventional audio reproduction apparatus of a type that performs the multichannel audio reproduction function and Zone-2 audio reproduction function. The audio reproduction apparatus of FIG. 18 is intended mainly for multichannel audio reproduction function. When analog audio signals ALIN and ARIN of two channels are input to input terminals 1-1 and 1-2, an A/D converter 2 converts the input analog audio signals ALIN and ARIN into digital audio signals. The thus-converted digital audio signals are passed to a digital signal processor (hereinafter referred to as a “DSP”) 4, where the audio signals are subjected to sound field processing as may be necessary. However, a further description of the input signals to input terminals 1-1 and 1-2 is omitted because these input signals are not multichannel audio inputs to be processed in accordance with the basic principles of the present invention.

When a digital sound signal DIN, compression-coded by the Dolby Digital, DTS or AAC technique, is supplied via an input terminal 1-3 and selector 3 to the DSP 4, the DSP 4 decompression-decodes the input compression-coded digital sound signal DIN by means of an internal decoder 401, to thereby generate various audio signals, i.e. main left and right signals L and R, rear left and right signals RL and RR, center signal C, rear center signal RC and subwoofer (low frequency) signal LFE.

The main left and right signals L and R and rear left and right signals RL and RR, output from a sound field processing section 402 of the DSP 4, are converted by a D/A converter 5 into analog signals, then passed via corresponding volume controls 6-1, 6-2 and 6-3, 6-4 to power amplifiers 7-1, 7-2 and 7-3, 7-4 for amplification, and then output through speaker terminals 8-1, 8-2 and 8-3, 8-4. Further, the subwoofer signal LFE, output from the sound field processing section 402 of the DSP 4, is converted by the D/A converter 5 into an analog signal, then passed to a corresponding volume control 6-7, and then output through a subwoofer output terminal 11.

When audio reproduction is not to be performed in the second zone, selector switches 9-1 and 9-2 are each caused to connect to a “Z1” (first-zone side) contact. In this case, the center signal C and rear center signal RC, output from the sound field processing section 402 of the DSP 4, are converted by the D/A converter 5 into analog signals, then passed, via corresponding volume controls 6-5 and 6-6 and selector switches 9-1 and 9-2, to power amplifiers 7-5 and 7-6 for amplification, and then output through speaker terminals 8-5 and 8-6, respectively.

When, on the other hand, the Zone-2 audio reproduction function is to be used or performed to deliver audio signals of two channels to the second zone, the selector switches 9-1 and 9-2 are each caused to connect to a Z2 (second-zone side) contact. In this case, analog audio signals Z2L and Z2R input to input terminals 1-4 and 1-5 are passed, via corresponding volume controls 6-8 and 6-9 and selector switches 9-1 and 9-2, to the power amplifiers 7-5 and 7-6 for amplification, and then output through the speaker terminals 8-5 and 8-6, respectively.

FIG. 19 is a plan view showing layout or arrangement of the speakers in the first zone Zone1 for performing the multichannel audio reproduction and in the second zone Zone2 for performing the two-channel audio reproduction. When the multichannel audio reproduction is to be performed in the first zone Zone1, the main left and right signals L, R, rear left and right signals RL, RR, center signal C and rear center signal RC, output from the speaker terminals 8-1, 8-2, 8-3, 8-4, 8-5 and 8-6, are supplied to main speakers SP-L, SP-C, rear speakers SP-RL, SP-RR, center speaker SP-C and rear center speaker SP-RC, respectively. The subwoofer signal LFE, output from the subwoofer output terminal 11, is supplied to a subwoofer SP-SW provided with a built-in amplifier. In FIG. 19, each reference character U represents a test-listening position; assume here that the selector switches 9-1 and 9-2 in the illustrated example, are each being connected to, or selecting, the Z1 contact.

When, on the other hand, audio signals of two channels are to be delivered to the second zone for two-channel audio reproduction in the second zone, the audio signals Z2L and Z2R of the two channels, output from the speaker terminals 8-5 and 8-6, are supplied to the speakers SP-Z2L and SP-Z2R, respectively.

In the audio reproduction apparatus of FIG. 18, where the amplifiers 7-5 and 7-6 and speakers 8-5 and 8-6 are shared between the multichannel audio reproduction function and the Zone-2 audio reproduction function, if there is a likelihood of the Zone-2 audio reproduction function being used, it is necessary to previously connect the speakers SP-Z2L and SP-Z2R of the second zone Zone2 with the speaker terminals 8-5 and 8-6 and connect each of the selector switches 9-1 and 9-2 to the Z2 contact, irrespective of whether or not the Zone-2 audio reproduction function is actually used in the second zone Zone2. Therefore, even where the center speaker SP-C and rear center speaker SP-RC are positioned in the first zone Zone1, the center and rear center signals C and RC are not supplied to these center and rear center speakers SP-C and SP-RC.

Namely, when the Zone-2 audio reproduction function is to be performed in the conventional audio reproduction apparatus having the multichannel audio reproduction function and if there can not be provided a specific number of power amplifiers corresponding to a necessary number of channels for the first zone Zone1 plus a necessary number of channels for the second zone Zone2, there arises a need to secure in advance a portion of the first-zone multichannel power amplifiers for use as one or more second-zone multichannel power amplifiers. Thus, the number of output channels of the first zone would come short, which would undesirably result in an insufficient multichannel audio reproduction effect in the first zone.

Recently, another type of multizone audio reproduction system has also become popular which are designed to deliver audio signals to a plurality of rooms using a single amplifier. In applications where the multizone audio reproduction function is to be performed using an audio reproduction apparatus, it has been known to provide an A group of main speakers in a first zone and a B group of main speakers in a second zone, and perform, via a main speaker changing switch of the audio reproduction apparatus, ON/OFF control on output to the A-group main speakers and output to the B-group main speakers independently of each other.

FIG. 20 is a block diagram illustrating a setup of such a conventional audio reproduction apparatus. When analog audio signals ALIN and ARIN of two channels are input to input terminals 1-1 and 1-2, an A/D converter 22 converts the input analog audio signals ALIN and ARIN into digital audio signals. The thus-converted digital audio signals are passed to a digital signal processor (DSP) 3, where the audio signals are subjected to sound field processing as may be necessary. When a digital sound signal DIN, compression-coded by the Dolby Digital, DTS or AAC technique, is input to an input terminal 1-3, the DSP 3 decompression-decodes the input compression-coded digital sound signal DIN by means of an internal decoder (not shown), to thereby generate various analog audio signals, i.e. main left and right signals L and R, rear left and right signals RL and RR, center signal C and subwoofer (low frequency) signal LFE.

When the DSP 3 is set in an OFF (or downmix) state (for two-channel audio reproduction), the main left and right signals L and R are output from the DSP 3, but, when the DSP 3 is set in an ON state (for multichannel audio reproduction), the main left and right signals L and R, rear left and right signals RL and RR, center signal C and subwoofer (low frequency) signal LFE are output from the DSP 3.

When audio reproduction is to be performed in the first zone, main speaker changing switches 16-1 and 16-2 are turned on. Thus, the main left and right signals L and R are amplified by power amplifiers 14-1 and 14-2, respectively, and then passed through the main speaker changing switches 16-1 and 16-2 to speaker output terminals 5-1 and 5-2 to be output therefrom. When multichannel audio reproduction is to be performed, the rear left and right signals RL, RR and center signal C, output from the DSP 3, are amplified by power amplifiers 14-3, 14-4 and 14-5, respectively, and then output from speaker output terminals 5-3, 5-4 and 5-5. Further, the subwoofer signal LFE output from the DSP 3 is output from a subwoofer output terminal 17. On the other hand, when audio signals are to be delivered to the second zone, main speaker changing switches 16-3 and 16-4 are turned on. Thus, the main left and right signals L and R, output from the DSP 3, are amplified by the power amplifiers 14-1 and 14-2, respectively, and then passed through the main speaker changing switches 16-3 and 16-4 to speaker output terminals 5-6 and 5-7 to be output therefrom.

FIG. 21 is a plan view showing layout or arrangement of the speakers in the first zone ZoneA capable of the multichannel audio reproduction and the speakers in the second zone ZoneB capable of the two-channel audio reproduction in the conventional audio reproduction apparatus of FIG. 20. In the figure, test-listening positions are each represented by reference character U. When the multichannel audio reproduction is to be performed in the first zone ZoneA, the main left and right signals L, R, rear left and right signals RL, RR and center signal C, output from the speaker terminals 5-1, 5-2, 5-3, 5-4 and 5-5, are supplied to main speakers SP-AL, SP-AR, rear speakers SP-RL, SP-RR and center speaker SP-C, respectively. The subwoofer signal LFE, output from the subwoofer output terminal 17, is supplied to a subwoofer SP-SW provided with a built-in amplifier. When, on the other hand, the audio signals of the two channels are to be delivered to the second zone ZoneB, the audio signals output from the speaker terminals 5-6 and 5-7 are supplied to the speakers SP-BL and SP-BR, respectively.

Namely, the conventional audio reproduction apparatus of FIG. 20 are constructed in such a manner that the output to the main speakers SP-AL and SP-AR of group A and the output to the main speakers SP-BL and SP-BR of group B can be subjected to ON/OFF control independently of each other; however, the conventional audio reproduction apparatus of FIG. 20 is constructed with no consideration as to whether the B-group speakers SP-BL and SP-BR are positioned in the first zone ZoneA or in the second zone ZoneB. Therefore, once the output to the A-group speakers SP-AL and SP-AR is turned off while the multichannel audio reproduction is being executed with the DSP 3 set in the ON state under the environment where the A-group speakers SP-AL and SP-AR are provided in the first zone ZoneA while the B-group speakers SP-BL and SP-BR are provided in the second zone ZoneB, there would arise a problem that only surround signals are reproduced in the first zone ZoneA. Another problem with the conventional audio reproduction apparatus of FIG. 20 is that, if the B-group speakers SP-BL and SP-BR are provided in the second zone ZoneB, no surround signal can be reproduced in the second zone ZoneB and thus no multichannel audio reproduction effect can be achieved in the second zone ZoneB.

### SUMMARY OF THE INVENTION

In view of the foregoing, it is an object of the present invention to provide an audio reproduction apparatus with a multichannel audio reproduction function which achieves a sufficient multichannel audio reproduction effect even where there is a need to allocate a portion of multichannel power amplifiers of a first zone to a second zone.

It is another object of the present invention to provide an audio reproduction apparatus which is capable of performing ON/OFF control on output to two groups of speaker output terminals independently of each other, and which, under an environment where two groups of main speakers are positioned in different (first and second) zones, can prevent reproduction of any unnecessary surround signal in the first zone when output to first speaker output terminals connected to main speakers in the first zone is OFF and output to second speaker output terminals connected to main speakers in the second zone is ON.

It is still another object of the present invention to provide an audio reproduction apparatus which is capable of performing ON/OFF control on output to two groups of speaker output terminals independently of each other, and which, under an environment where two groups of main speakers are positioned in different (first and second) zones, achieves a sufficient multichannel audio reproduction effect in the second zone having only the main speakers positioned therein.

The present invention provides an audio reproduction apparatus of a type having: a first mode for performing multichannel audio reproduction to deliver first audio signals of n (n is an integral number in a range of n≧4) channels from power amplifiers of the n channels to a first zone; and a second mode for performing multizone audio reproduction to deliver, from the power amplifier of m channel (m is an integral number in a range of 1≦m<n) not used for the multichannel audio reproduction, a second audio signal of the m channel to the second zone while performing multichannel audio reproduction to deliver the first audio signals of (n−m) channels from the power amplifiers of the (n−m) channels to the first zone. The audio reproduction apparatus of the present invention is characterized by comprising: a digital signal processor (DSP) that processes the first audio signals of the n channels and outputs the processed first audio signals to the power amplifiers of the n channels; a first selector switch connected to the input of the power amplifier of the m channel, which, in the first mode, selects the first audio signal of the m channel, corresponding to the power amplifier of the m channel, from among the first audio channels of the n channels outputted by the digital signal processor, but, in the second mode, selects the second audio signal of the m channel; and a second selector switch connected to the output of the power amplifier of the m channel, which, in the first mode, couples the output of the power amplifier of the m channel to a speaker terminal provided for the first zone, but, in the second mode, couples the output of the power amplifier of the m channel to a speaker terminal provided for the second zone. In the second mode, the digital signal processor of the present invention performs sound field correction on at least a portion of the first audio signals of the (n−m) channels so that a sound field of the first zone has a desired characteristic.

In one embodiment of the present invention, a particular volume control is shared between sound volume adjustment of the first audio signal of the m channel and sound volume adjustment of the second audio signal of the m channel.

In one embodiment of the present invention, the audio reproduction apparatus further comprises a control section that, as switching takes place from the first mode to the second mode, stores a current value of the volume control of the m channel, having been adjusting a sound volume of the first audio signal, as a volume value for the first zone and sets a prestored volume value for the second zone in the volume control of the m channel. On the other hand, as switching takes place from the second mode to the first mode, the control section of the audio reproduction apparatus stores a current value of the volume control of the m channel, having been adjusting a sound volume of the second audio signal, as a volume value for the second zone and sets a prestored volume value for the first zone in the volume control of the m channel.

According to another aspect of the present invention, there is provided an audio reproduction apparatus of a type that supplies main signals, to be reproduced in front of a human listener, to main speakers and supplies surround signals to surround speakers so as to give the human listener a surround feeling. The audio reproduction apparatus of the present invention is characterized by comprising: a digital signal processor (DSP) that outputs the surround signals; a power amplifier that amplifies the main signals; an output switching member operable to perform ON/OFF control on output from the power amplifier to first (A-group) speaker output terminals and output from the power amplifier to second (B-group) speaker output terminals independently of each other; and a mode setting section that can select either one of a first mode where speakers connected to the first speaker output terminals and speakers connected to the second speaker output terminals are both positioned and used in a first zone, and a second mode where the speakers connected to the first speaker output terminals are positioned and used in the first zone and the speakers connected to the second speaker output terminals are positioned and used in a second zone. When the output to the first speaker output terminals is off while the output to the second speaker output terminals is on and the second mode is selected by the mode setting section, the digital signal processor stops outputting the surround signals.

In one embodiment, when the output to the first speaker output terminals is off while the output to the second speaker output terminals is on and the second mode is selected by the mode setting section, the digital signal processor imparts an effect sound to the main signal.

The following will describe embodiments of the present invention, but it should be appreciated that the present invention is not limited to the described embodiments and various modifications of the invention are possible without departing from the basic principles of the invention. The scope of the present invention is therefore to be determined solely by the appended claims.

### BRIEF DESCRIPTION OF THE DRAWINGS

For better understanding of the object and other features of the present invention, its preferred embodiments will be described hereinbelow in greater detail with reference to the accompanying drawings, in which:

FIG. 1 is a block diagram showing a setup of an audio reproduction apparatus in accordance with a first embodiment of the present invention;

FIG. 2 is a flow chart showing operations performed by the first embodiment of the audio reproduction apparatus of FIG. 1 as the Zone-2 audio reproduction function is turned on and off;

FIG. 3 is a block diagram showing a setup of an audio reproduction apparatus in accordance with a second embodiment of the present invention;

FIG. 4 is a flow chart showing operations performed by the second embodiment of the audio reproduction apparatus of FIG. 3 as the Zone-2 audio reproduction function is turned on and off;

FIG. 5 is a block diagram showing a setup of an audio reproduction apparatus in accordance with a third embodiment of the present invention;

FIG. 6 is a plan view showing layout or arrangement of speakers in a first zone and speakers in a second zone employed in the third embodiment of FIG. 5;

FIG. 7 is a block diagram showing a setup of an audio reproduction apparatus in accordance with a fourth embodiment of the present invention;

FIG. 8 is a plan view showing arrangement of speakers in a first zone and speakers in a second zone employed in the fourth embodiment of FIG. 7;

FIG. 9 is a block diagram showing a setup of an audio reproduction apparatus in accordance with a fifth embodiment of the present invention;

FIG. 10 is a flow chart showing operations performed by the audio reproduction apparatus of FIG. 9 as switching takes place between groups of main speakers;

FIG. 11 is a block diagram showing an example of an effect sound impartment process performed by a DSP in the fifth embodiment of FIG. 9;

FIG. 12 is a block diagram showing a setup of an audio reproduction apparatus in accordance with a sixth embodiment of the present invention;

FIG. 13 is a plan view showing arrangement of speakers in first and second zones employed in the sixth embodiment FIG. 12;

FIG. 14 is a block diagram showing an example of an effect sound impartment process performed by a DSP in the sixth embodiment FIG. 12;

FIG. 15 is a block diagram showing an audio reproduction apparatus in accordance with a seventh embodiment of the present invention;

FIG. 16 is a plan view showing arrangement of speakers in first and second zones employed in the seventh embodiment of FIG. 7;

FIG. 17 is a block diagram showing an example of an effect sound impartment process performed by a DSP in the seventh embodiment FIG. 15;

FIG. 18 is a block diagram illustrating a setup of a conventional audio reproduction apparatus;

FIG. 19 is a plan view showing arrangement of speakers in a first zone for performing multichannel audio reproduction and in a second zone for performing two-channel audio reproduction;

FIG. 20 is a block diagram illustrating a setup of another conventional audio reproduction apparatus; and

FIG. 21 is a plan view showing arrangement of speakers in a first zone for performing multichannel audio reproduction and in a second zone for performing two-channel audio reproduction in the conventional audio reproduction apparatus of FIG. 20.

### DETAILED DESCRIPTION OF THE INVENTION

### First Embodiment

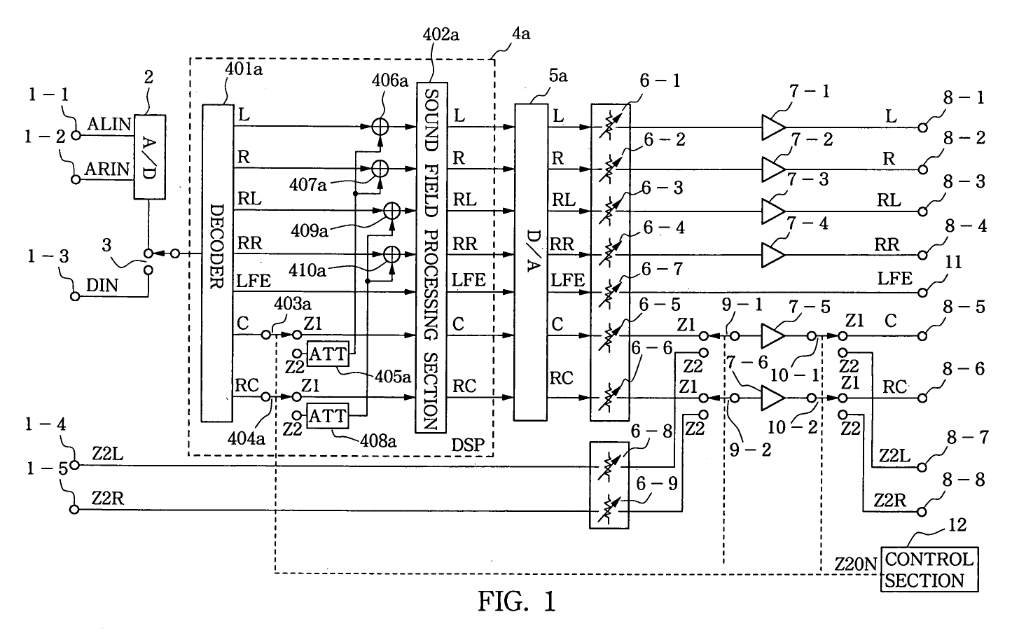

FIG. 1 is a block diagram showing a setup of an audio reproduction apparatus in accordance with a first embodiment of the present invention. The audio reproduction apparatus of FIG. 1 includes input terminals 1 (1-1, 1-2, 1-3, 1-4 and 1-5), an A/D converter 2, a selector 3, a DSP 4a, a D/A converter 5a, volume controls 6 (6-1, 6-2, 6-3, 6-4, 6-5, 6-6, 6-7, 6-8 and 6-9), power amplifiers 7 (7-1, 7-2, 7-3, 7-4, 7-5 and 7-6), speaker terminals 8 (8-1, 8-2, 8-3, 8-4, 8-5, 8-6, 8-7 and 8-8), first selector switches 9 (9-1 and 9-2), second selector switches 10 (10-1 and 10-2), a subwoofer output terminal 11, and a control section 12.

The power amplifiers 7 are provided in corresponding relation to n (n is an integral number equal to or greater than “4” (n≧4); in the instant embodiment, n=6) channels. Of the n channels, m (1≦m<n; in the instant embodiment, m=2) channels are used for the Zone-2 audio reproduction. When a digital sound signal DIN, compression-coded by the Dolby Digital, DTS or AAC, is supplied from the input terminal 1-3 via the selector 3, a decoder 401a of the DSP 4a decompression-decodes the input compression-coded digital sound signal DIN, to thereby generate various audio signals (first audio signals), i.e. main left and right signals L and R, rear left and right signals RL and RR, center signal C, rear center signal RC and subwoofer (low frequency) signal LFE.

The thus-generated audio signals are passed, via a sound processing section 402a for performing various sound field processing, to the D/A converter 5a, where the signals are converted into analog signals. The main left and right signals L, R and rear left and right signals RL, RR, output from the D/A converter 5a, are passed via the corresponding volume controls 6-1, 6-2 and 6-3, 6-4 to the power amplifiers 7-1, 7-2 and 7-3, 7-4 for amplification, and then output through the speaker terminals 8-1, 8-2 and 8-3, 8-4. The subwoofer signal LFE output from the D/A converter 5a is sent via the volume control 6-7 to the subwoofer output terminal 11.

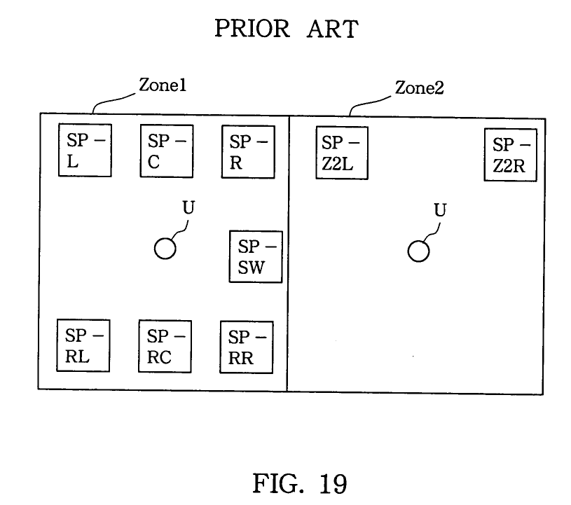

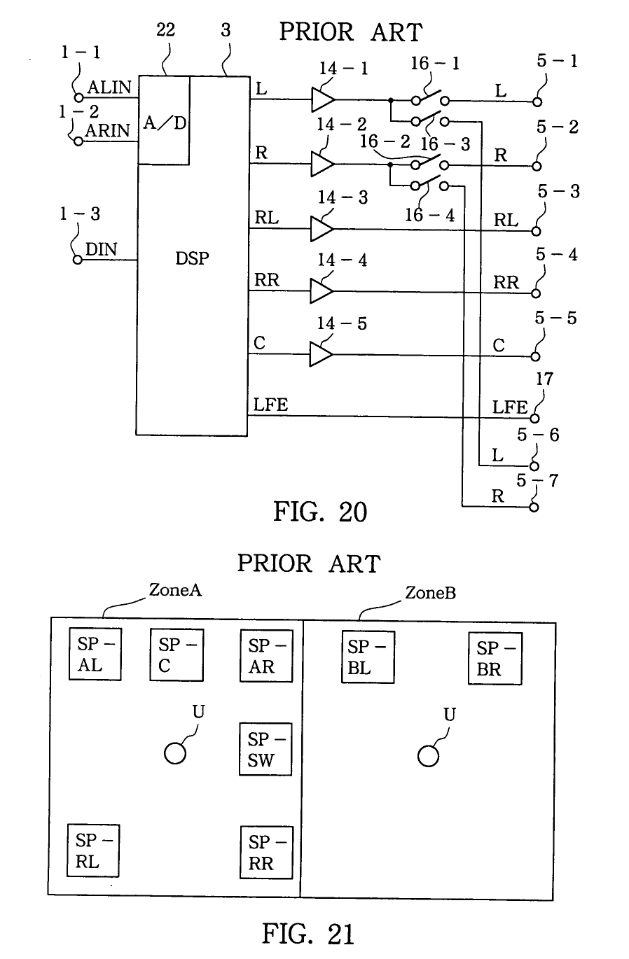

In the instant embodiment, speakers are arranged in the first and second zones Zone1 and Zone2 in the same manner as shown in and described earlier in relation to FIG. 19. The speaker terminals 8-1, 8-2, 8-3, 8-4, 8-5 and 8-6 are connected to the main speakers SP-L, SPSP-C, rear speakers SP-RL, SP-RR, center speaker SP-C and rear center speaker SP-RC, respectively, of the first zone Zone1. The subwoofer output terminal 11 is connected to a subwoofer SP-SW provided with a built-in amplifier.

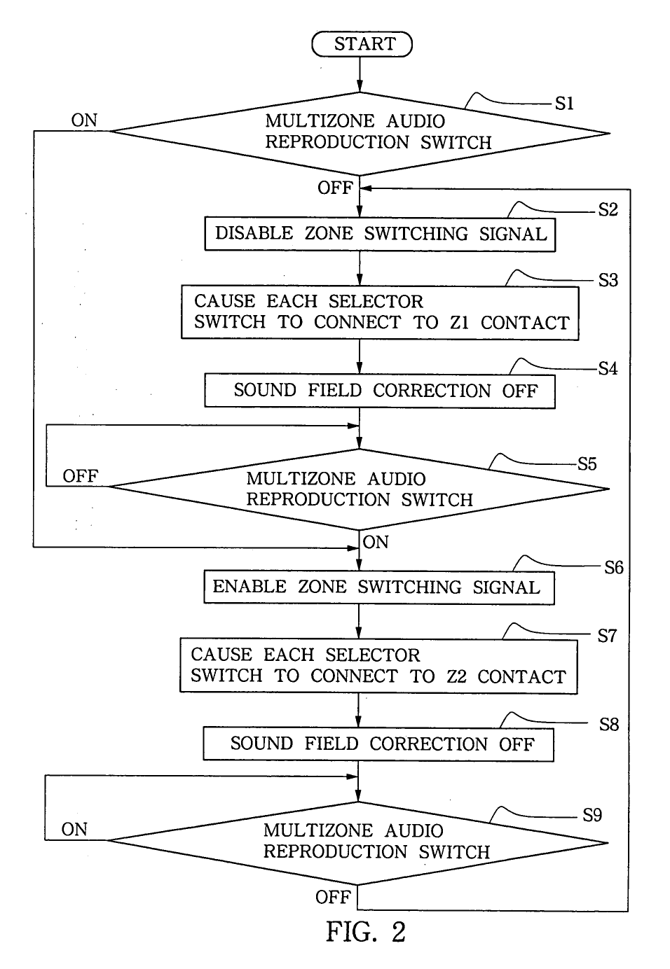

FIG. 2 is a flow chart showing operations performed by the audio reproduction apparatus of FIG. 1 as the Zone-2 audio reproduction function is turned on and off. When the Zone-2 audio reproduction function is not to be used, a user turns off a Zone-2 audio reproduction switch (not shown) of the audio reproduction apparatus. If the Zone-2 audio reproduction switch is OFF as determined at step S1 of FIG. 2, the control section 12 invalidates or disables a zone switching signal Z2ON at step S2. Thus disabling the zone switching signal Z2ON causes each of the selector switches 9-1, 9-2, 10-1 and 10-2 to connect to a Z1 (first-zone side) contact, at step S3. Also, disabling the zone switching signal Z2ON switches each of switches 403a and 404a of the DSP 4a to connect to the Z1 contact, so that sound field correction to be later described is turned off at step S4.

Consequently, the center signal C and rear center signal RC, output from the D/A converter 5a, are sent via the corresponding volume controls 6-5 and 6-6 and selector switches 9-1 and 9-2, to the power amplifiers 7-5 and 7-6 for amplification, and the thus-amplified center signal C and rear center signal RC are then passed via the selector switches 10-1 and 10-2 to the speaker terminals 8-5 and 8-6 to be output therefrom. In this manner, 6.1-channel audio reproduction is performed in the first zone Zone1.

When, on the other hand, the Zone-2 audio reproduction function is to be used to deliver audio signals of two channels to the second zone Zone2, the user turns on the Zone-2 audio reproduction switch of the audio reproduction apparatus. If the Zone-2 audio reproduction switch is ON as determined at step S5 of FIG. 2, the control section 12 enables the zone switching signal Z2ON at step S6. Thus enabling the zone switching signal Z2ON causes each of the selector switches 9-1, 9-2, 10-1 and 10-2 to connect to the Z2 contact, at step S7. In this way, analog audio signals (second audio signals) Z2L and Z2R, input to the input terminals 1-4 and 1-5, are sent via the corresponding volume controls 6-8 and 6-9 and selector switches 9-1 and 9-2, to the power amplifiers 7-5 and 7-6 for amplification, and the thus-amplified signals are then passed via the selector switches 10-1 and 10-2 to the speaker terminals 8-7 and 8-8 to be output therefrom. Because the speaker terminals 8-7 and 8-8 are connected to the speakers SP-Z2L and SP-Z2R of the second zone Zone2, 2-channel audio reproduction is executed in the second zone.

Also, in response to the enabling of the zone switching signal Z2ON, the switches 403a and 404a within the DSP 4a are caused to connect to the Z2 contact. Thus, in order to compensate for reduction in the multichannel audio reproduction effect due to stoppage of supply, to the speakers SP-C and SP-RC in the first zone Zone1, of the center signal C and rear center signal RC, the sound field correction is performed on the main left and right signals L and R and rear left and right signals RL and RR to be supplied to the first zone Zone1, at step S8.

For execution of 6.1-channel multichannel audio reproduction by the main speakers SP-L and SP-R, rear speakers SP-RL and SP-RR and subwoofer SP-SW, the instant embodiment is arranged to allocate and add the center signal C and rear center signal RC to the main left and right signals L, R and rear left and right signals RL, RR so that the center signal C and rear center signal RC are supplied together with the main left and right signals L, R and rear left and right signals RL, RR. Namely, because it is only necessary for the center signal C to be localized between the main left and right signals L and R, the center signal C may be allocated and added to the main left and right signals L and R. Similarly, because it is only necessary for the rear center signal RC to be localized between the rear left and right signals RL and RR, the rear center signal RC may be allocated and added to the rear left and right signals RL and RR.

When the sound field correction is to be executed at step S8, the center signal C output from the decoder 401a is passed via the switch 403a to an attenuator 405a for adjustment to an appropriate level, and then the level-adjusted center signal C is added to the main left and right signals L and R via adders 406a and 407a. Also, the rear center signal RC output from the decoder 401a is passed via the switch 404a to an attenuator 408a for adjustment to an appropriate level, and then the level-adjusted rear center signal RC is added to the rear left and right signals RL and RR via adders 409a and 410a. The main left and right signals L, R and rear left and right signals RL, RR, having been subjected to the sound field correction, are sent via the sound processing section 402a to the D/A converter 5a for conversion into analog signals, and the thus-converted analog signals are passed via the corresponding volume controls 6-1, 6-2 and 6-3, 6-4 to the power amplifiers 7-1, 7-2 and 7-3, 7-4 for amplification. Then, the thus-amplified analog signals are output through the speaker output terminals 8-1, 8-2 and 8-3, 8-4. Further, the subwoofer signal LFE, output from the audio processing section 402a, is converted into an analog signal by the D/A converter 5a and output via the subwoofer output terminal 11 after having been processed by the volume control 6-7.

Note that respective gains of the main left and right signals L and R, rear left and right signals RL and RR, center signal C and rear center signal RC are set for the sound field correction such that the sound fields in the first zone Zone1 have desired characteristics.

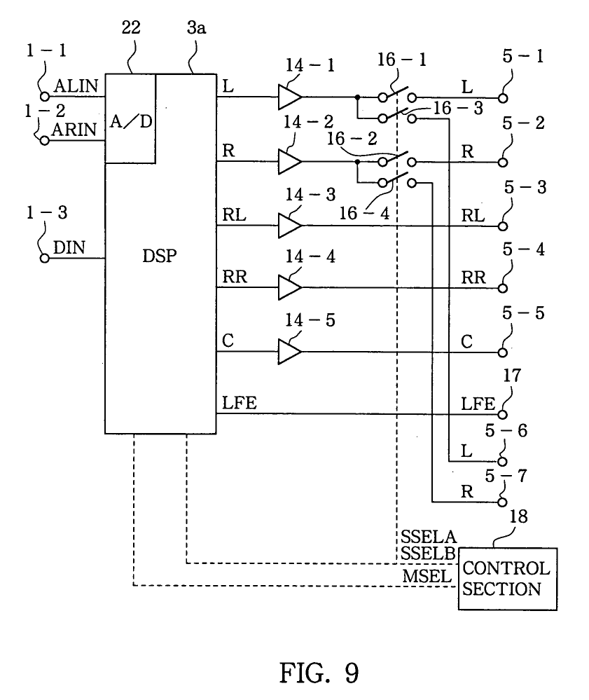

Namely, the instant embodiment is constructed by adding the selector switches 10-1 and 10-2 and speaker terminals 8-7 and 8-8 to the basic structure of the conventional audio reproduction apparatus of FIG. 9. When no actual audio reproduction is to be executed in the second zone Zone2, the selector switches 10-1 and 10-2 are each caused to connect to the Z1 contact, so that the center signal C and rear center signal RC can be supplied to the speakers SP-C and SP-RC of the first zone Zone1 and thus the maximum multichannel audio reproduction effect can be obtained.

When, on the other hand, actual audio reproduction is to be actually executed in the second zone Zone2, the sound field correction is performed by the DSP 4a on the main left and right signals L and R and rear left and right signals RL and RR, so that the instant embodiment can appropriately compensate for reduction in the multichannel audio reproduction effect in the first zone.

Note that, during the course of switching operations of the selector switches 9-1, 9-2, 10-1 and 10-2 and the switches 403a and 404a within the DSP 4a at steps S2 to S4 and S6 to S8 of FIG. 2, the instant embodiment performs further operations, for example, for turning off all outputs of the sound processing section 402a, so as to prevent undesired sounds from being produced inadvertently due to switching time differences etc.

### Second Embodiment

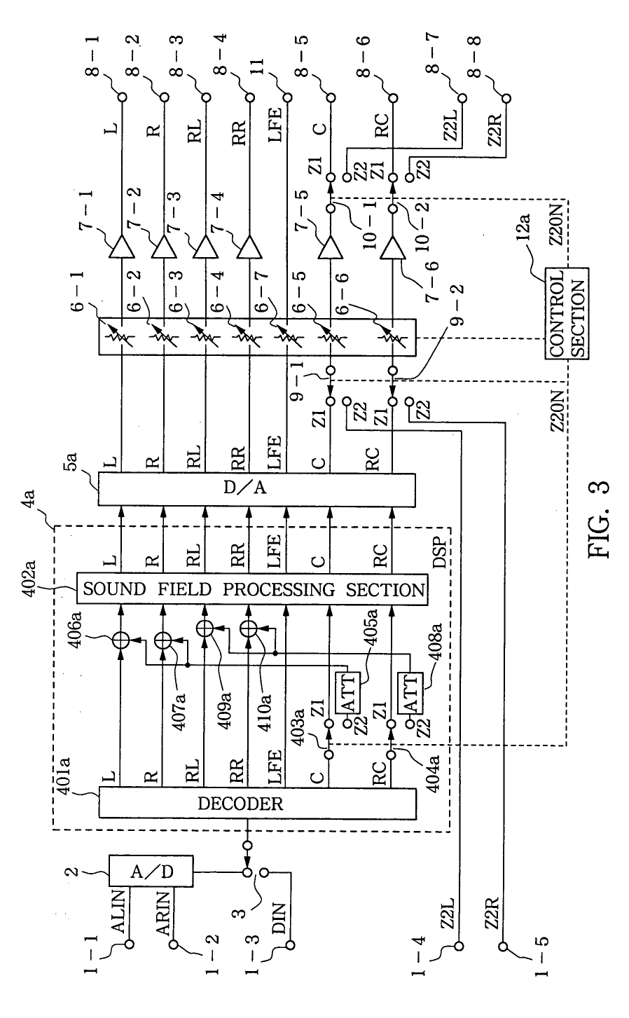

FIG. 3 is a block diagram showing a setup of an audio reproduction apparatus in accordance with a second embodiment of the present invention, where the same elements as in the embodiment of FIG. 1 are represented by the same reference characters as in FIG. 1. Whereas the first embodiment has been described as including the sound-volume adjusting volume controls 6-8 and 6-9 for the second zone Zone2 separately from the sound-volume adjusting volume controls 6-1 to 6-6 for the first zone Zone1, the second embodiment is characterized in that the volume controls 6-5 and 6-6 are shared between the first zone Zone1 (signals C and RC) and the second zone Zone2 (signals Z2L and Z2R). Control section 12a has, in addition to the functions of the control section 12 in the first embodiment, a function of setting values of the volume controls 6-5 and 6-6 when the Zone-2 audio reproduction switch is turned on or off.

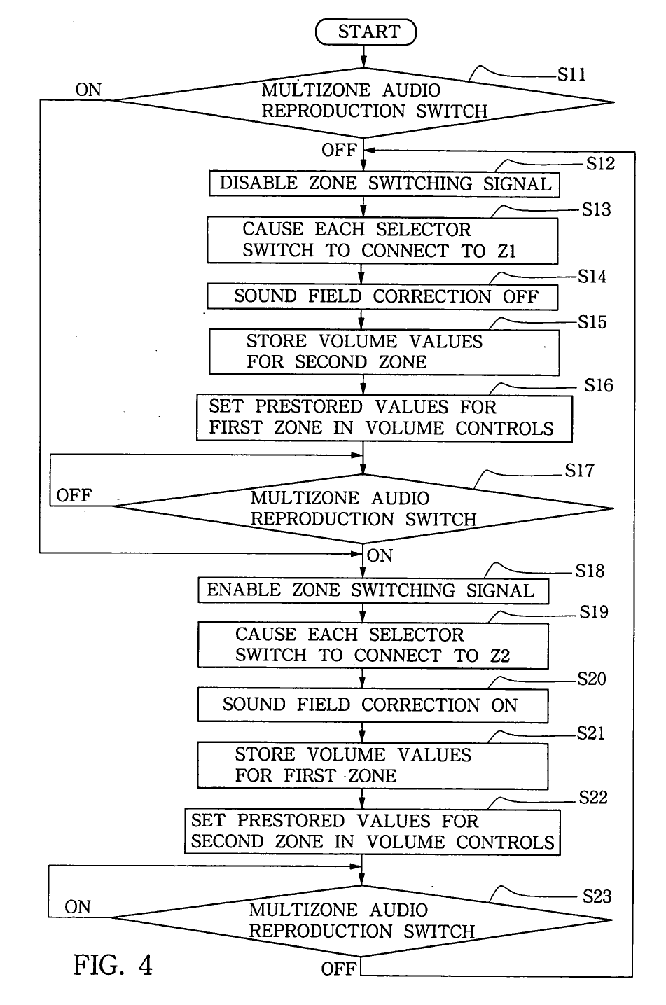

FIG. 4 is a flow chart showing operations performed by the audio reproduction apparatus of FIG. 3 as the Zone-2 audio reproduction function is turned on and off. The operations of step S12, S13 and S14 performed when the Zone-2 audio reproduction switch of the audio reproduction apparatus is turned off (determined as “OFF” at step S11) are similar to those of steps S2, S3 and S4 of FIG. 2.

Once the Zone-2 audio reproduction switch is shifted from the ON state to the OFF state, the control section 12a invalidates or disables the zone switching signal Z2ON at step S12, and it also stores, as volume values V2-5 and V2-6 for the second zone Zone2, values of the volume controls 6-5 and 6-6 immediately before the turning-off of the Zone-2 audio reproduction switch, at step S15. In addition, at step S16, prestored volume values V1-5 and V1-6 for the first zone Zone1 are set in the volume controls 6-5 and 6-6, respectively. Note that all of the volume controls are preset at predetermined values prior to shipment from the factory.

The operations of step S18, S19 and S20 performed when the Zone-2 audio reproduction switch of the audio reproduction apparatus is turned on are similar to those of steps S6, S7 and S8 of FIG. 2. Namely, the control section 12a enables the zone switching signal Z2ON at step S18, and at step S21, it also stores, as volume values V1-5 and V1-6 for the first zone Zone1, values of the volume controls 6-5 and 6-6 immediately before the turning-on of the zone switching signal Z2ON. In addition, at step S22, prestored volume values V2-5 and V2-6 for the second zone Zone2 are set in the volume controls 6-5 and 6-6, respectively.

That is, in the second embodiment, the volume controls 6-5 and 6-6 are shared between the first zone Zone1 and the second zone Zone2 so that the volume controls 6-8 and 6-9 for the second zone Zone2 can be dispensed with. As a consequence, the second embodiment can significantly reduce the number of the necessary components as compared with the first embodiment.

Further, according to the second embodiment, the volume values V1-5 and V1-6 for the first zone Zone1 are set in the volume controls 6-5 and 6-6 when the Zone-2 audio reproduction function is not to be used and the volume values V2-5 and V2-6 for the second zone Zone2 are set in the volume controls 6-5 and 6-6 when the Zone-2 audio reproduction function is to be used. With such arrangements, the second embodiment can eliminate a need for the user to re-set the volume controls 6-5 and 6-6 in accordance with the ON/OFF state of the Zone-2 audio reproduction function, thereby enhancing convenience for the user (user friendliness).

Note that, during the course of switching operations of the selector switches 9-1, 9-2, 10-1 and 10-2 and the switches 403a and 404a within the DSP 4a for setting values in the volume controls 6-6 and 6-6 at steps S12 to S16 and S18 to S22 of FIG. 4, the instant embodiment performs operations, for example, for turning off all outputs of the sound processing section 402a, so as to prevent undesired sounds from being produced inadvertently due to switching time differences etc.

### Third Embodiment

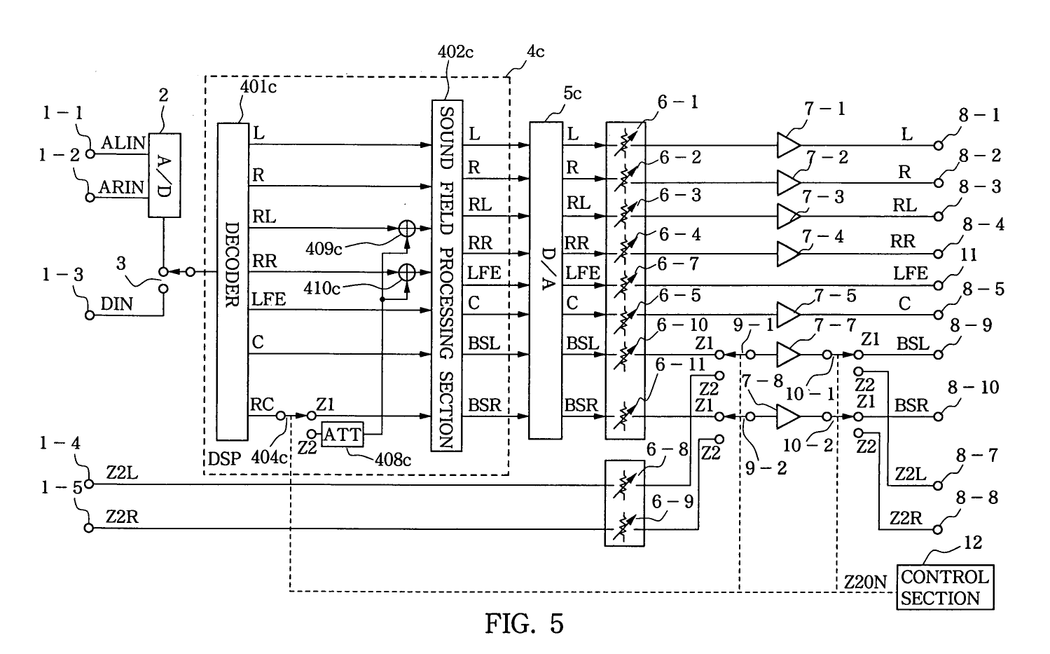

FIG. 5 is a block diagram showing a setup of an audio reproduction apparatus in accordance with a third embodiment of the present invention, where the same elements as in the embodiment of FIG. 1 are represented by the same reference characters as in FIG. 1. The third embodiment is characterized by applying the basic principles of the present invention to an audio reproduction apparatus provided with built-in power amplifiers for n (=7) channels. Specifically, in the third embodiment, the selector switches 9-1 and 9-2 are provided between the volume controls 6-10 and 6-11 and the power amplifiers 7-7 and 7-8, and the selector switches 10-1 and 10-2 are provided between the power amplifiers 7-7 and 7-8 and the speaker terminals 8-9 and 8-10.

Decoder 401c of a DSP 4c generates, on the basis of a digital audio signal output from the selector 3, various audio signals, i.e. main left and right signals L and R, rear left and right signals RL and RR, center signal C, rear center signal RC and subwoofer signal LFE, and it sends the thus-generated audio signals to a sound field processing section 402c.

The sound field processing section 402c outputs each of the main left and right signals L and R, rear left and right signals RL and RR, center signal C, subwoofer signal LFE and rear surround signals BSL and BSR (first audio signals) to a D/A converter 5c. At that time, the sound field processing section 402c generates the rear surround signals BSL and BSR on the basis of the rear center signal RC.

The D/A converter 5c converts each of the audio signals from the DSP 4c into an analog signal. The main left and right signals L and R and rear left and right signals RL and RR, output from the D/A converter 5c, are processed in generally the same manner as in the first embodiment. The center signal C output from the D/A converter 5c is sent through the volume control 6-5 to the power amplifier 7-5 for amplification, and the thus-amplified center signal C is then output via the speaker terminal 8-5.

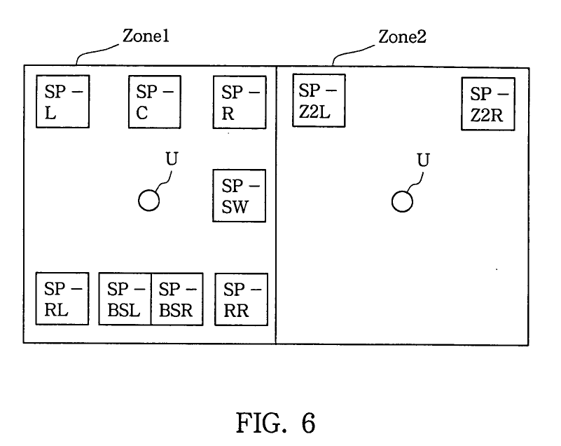

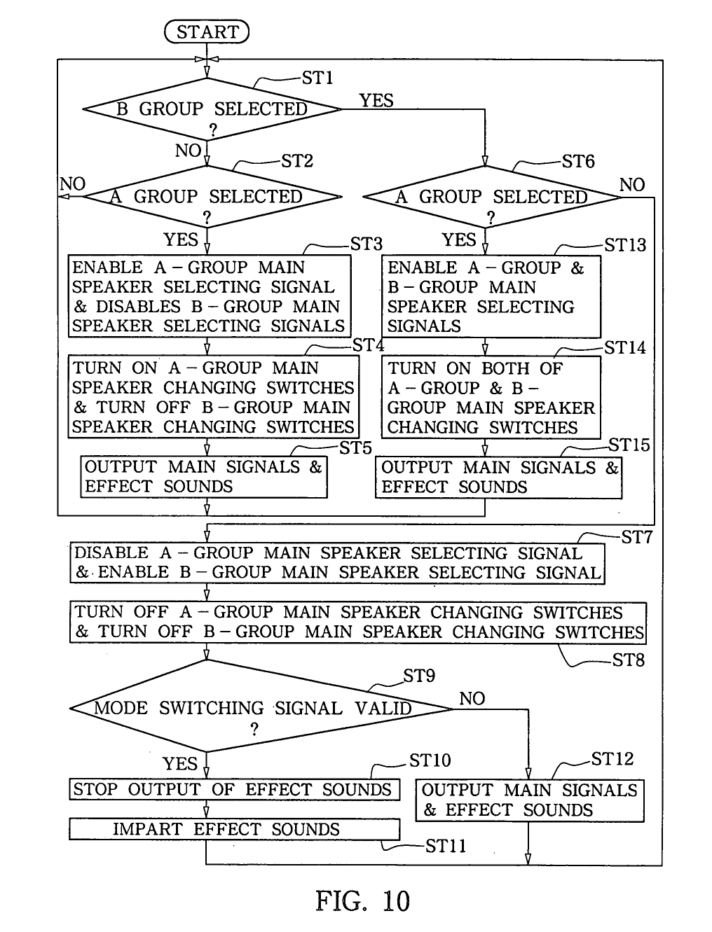

FIG. 6 is a plan view showing arrangement of speakers in the first zone Zone1 and in the second zone Zone2 employed in the audio reproduction apparatus of FIG. 5. In the third embodiment, rear surround speakers SP-BSL and SP-BSR are employed in place of the rear center speaker SP-RC of the first zone Zone1 described above in relation to FIG. 10, and the speaker terminals 8-9 and 8-10 are connected to the rear surround speakers SP-BSL and SP-BSR, respectively.

Operations performed by the audio reproduction apparatus of FIG. 5 as the Zone-2 audio reproduction function is turned on and off are similar to those performed in the first embodiment, except that the terms “center signal C” and “rear center signal RC” are replaced with “rear surround signal BSL” and “rear surround signal BSR”, respectively. Thus, the operations performed by the audio reproduction apparatus of FIG. 5 as the Zone-2 audio reproduction function is turned on and off will be described with reference to FIG. 2.

Namely, if the Zone-2 audio reproduction switch is turned off as determined at step S1 of FIG. 2, the zone switching signal Z2ON is disabled at step S2, and each of the selector switches 9-1, 9-2, 10-1 and 10-2 is caused to connect to the Z1 contact at step S3. Also, a switch 404c within the DSP 4c is caused to connect to the Z1 contact, at step S4.

The rear surround signals BSL and BSR, output from the DSP 4c, are converted by the D/A converter 5c into analog signals and then sent via the corresponding volume controls 6-10 and 6-11 and selector switches 9-1 and 9-2, to the power amplifiers 7-7 and 7-8 for amplification. Then, the thus-amplified rear surround signals BSL and BSR are passed via the selector switches 10-1 and 10-2 to the speaker terminals 8-9 and 8-10 to be output therefrom. In this manner, 7.1-channel audio reproduction is performed in the first zone Zone1.

On the other hand, if the Zone-2 audio reproduction switch is turned on as determined at step S5 of FIG. 2, the zone switching signal Z2ON is enabled at step S6, so that each of the selector switches 9-1, 9-2, 10-1 and 10-2 is caused to connect to the Z2 contact, at step S7. In this way, analog audio signals Z2L and Z2R, input to the input terminals 1-4 and 1-5, are sent via the corresponding volume controls 6-8 and 6-9 and selector switches 9-1 and 9-2, to the power amplifiers 7-7 and 7-8 for amplification, and the thus-amplified signals are then passed via the selector switches 10-1 and 10-2 to the speaker terminals 8-7 and 8-8 to be output therefrom.

Also, in response to the enabling of the zone switching signal Z2ON, the switch 404c within the DSP 4c is caused to connect to the Z2 contact. Thus, in order to compensate for reduction in the multichannel audio reproduction effect due to stoppage of supply, to the rear surround speakers SP-BSL and SP-BSR in the first zone Zone1, of the rear surround signals BSL and BSR, sound field correction is performed on the rear left and right signals RL and RR to be supplied to the first zone Zone1, at step S8.

As stated above, the rear surround signals BSL and BSR are generated on the basis of the rear center signal RC. Thus, by allocating the rear center signal RC, generated by the decoder 401c, to the rear left and right signals RL and RR, it is possible to execute 7.1-channel multichannel audio reproduction using the main speakers SP-L and SP-R, center speaker SP-C, rear speakers SP-RL and SP-RR and subwoofer SP-SW.

When the sound field correction is to be executed at step S8, the rear center signal RC output from the decoder 401c is passed via the switch 404c to an attenuator 408c for adjustment to an appropriate level, and then the level-adjusted rear center signal is added to the rear left and right signals RL and RR via adders 409c and 410c.

The rear left and right signals RL and RR, main left and right signals L and R, center signal C and subwoofer signal LFE, having been subjected to the sound field correction, are sent via the sound processing section 402c to the D/A converter 5c for conversion into analog signals, and the thus-converted rear left and right signals RL and RR, main left and right signals L and R and subwoofer signal LFE, output from the D/A converter 5c, are processed in generally the same manner as in the first embodiment. The converted center signal C from the D/A converter 5c is passed via the corresponding volume control 6-5 to the power amplifier 7-5 for amplification, and then the thus-amplified center signal C is output through the speaker output terminal 8-5.

Note that respective gains of the rear left and right signals RL and RR and rear center signal RC are set for the sound field correction such that the sound fields in the first zone Zone1 have desired characteristics.

With the above-described arrangements, the third embodiment provided with 7-channel built-in power amplifiers can achieve the same benefits as the first embodiment. In the third embodiment of FIG. 5, the volume controls 6-10 and 6-11 can be shared between the first zone Zone1 and the second zone Zone2, by providing the selector switches 9-1 and 9-2 between the D/A converter 5c and the volume controls 6-10 and 6-11 and controlling the values of the volume controls 6-10 and 6-11 via the control section 12a, in response to turning on/off of the Zone-2 audio reproduction switch, in generally the same manner as in the above-described second embodiment. As a consequence, the third embodiment can achieve the same benefits as the second embodiment.

### Fourth Embodiment

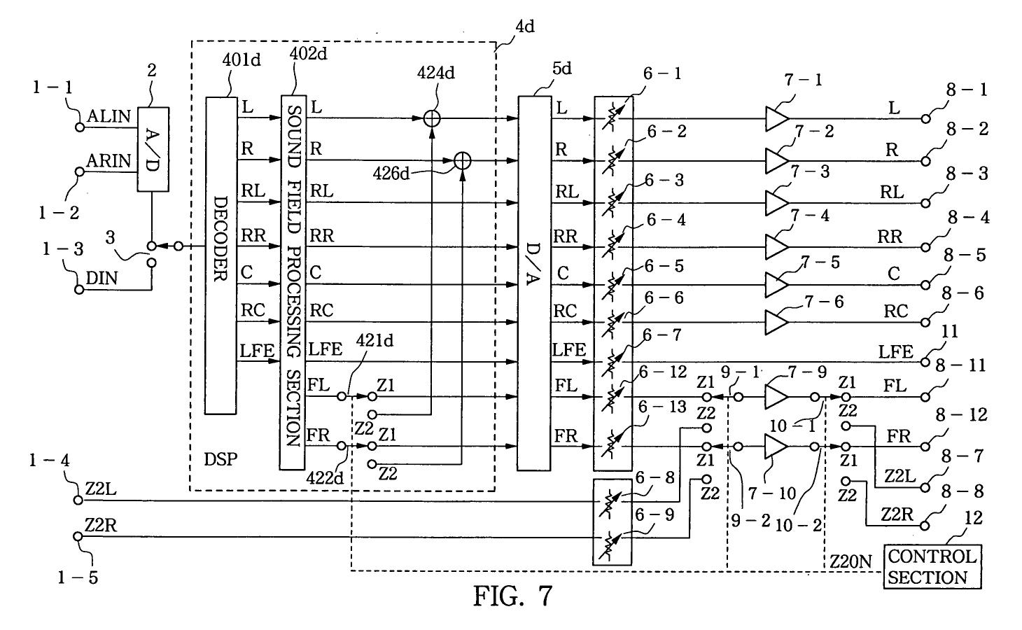

FIG. 7 is a block diagram showing a setup of an audio reproduction apparatus in accordance with a fourth embodiment of the present invention, where the same elements as in the embodiment of FIG. 1 are represented by the same reference characters as in FIG. 1. The fourth embodiment of FIG. 7 is characterized by applying the basic principles of the present invention to an audio reproduction apparatus provided with built-in power amplifiers for n (=8) channels. Specifically, in the fourth embodiment, the selector switches 9-1 and 9-2 are provided between the volume controls 6-12 and 6-13 and the power amplifiers 7-9 and 7-10, and the selector switches 10-1 and 10-2 are provided between the power amplifiers 7-9 and 7-10 and the speaker terminals 8-11 and 8-12.

Decoder 401d of a DSP 4d generates, on the basis of a digital audio signal output from the selector 3, various audio signals, i.e. main left and right signals L and R, rear left and right signals RL and RR, center signal C, rear center signal RC and subwoofer signal LFE, and it sends the thus-generated audio signals to a sound field processing section 402d.

The sound field processing section 402d outputs each of the main left and right signals L and R, rear left and right signals RL and RR, center signal C, rear center signal RC and front left and right signals FL and FR to a D/A converter 5d. At that time, the sound field processing section 402d generates the front left and right signals FL and FR on the basis of the main left and right signals L and R, rear left and right signals RL and RR, center signal C and rear center signal RC.

The D/A converter 5d converts each of the audio signals from the DSP 4d into an analog signal. The main left and right signals L and R and rear left and right signals RL and RR, output from the D/A converter 5d, are processed in generally the same manner as in the first embodiment. The center signal C and rear center signal RC, output from the D/A converter 5d, are sent through the volume controls 6-5 and 6-6 to the power amplifiers 7-5 and 7-6 for amplification, and the thus-amplified center signals C and RC are then output via the speaker terminals 8-5 and 8-6.

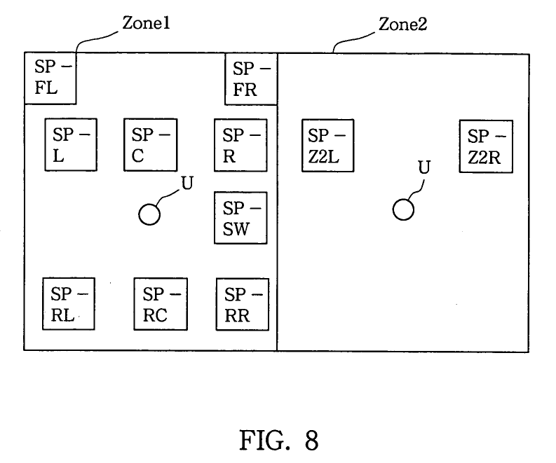

FIG. 8 is a plan view showing arrangement of speakers in the first zone Zone1 and in the second zone Zone2 employed in the audio reproduction apparatus of FIG. 7. In the fourth embodiment, front speakers SP-FL and SP-FR are added to the speakers of the first zone described above in relation to FIG. 10. The speaker terminals 8-11 and 8-12 are connected to the front speakers SP-FL and SP-FR, respectively.

Operations performed by the audio reproduction apparatus of FIG. 7 as the Zone-2 audio reproduction function is turned on and off are similar to those performed in the first embodiment, except that the terms “center signal C” and “rear center signal RC” are replaced with “front signal FL” and “front signal FR”, respectively. Thus, the operations performed by the audio reproduction apparatus of FIG. 7 as the Zone-2 audio reproduction function is turned on and off will be described with reference to FIG. 2.

Namely, if the Zone-2 audio reproduction switch is turned off as determined at step S1 of FIG. 2, the zone switching signal Z2ON is disabled at step S2, and each of the selector switches 9-1, 9-2, 10-1 and 10-2 is caused to connect to the Z1 contact at step S3. Also, switches 421d and 422d within the DSP 4d are each caused to connect to the Z1 contact, at step S4.

Thus, the front left and right signals FL and FR, output from the DSP 4d, are converted by the D/A converter 5d into analog signals and then sent via the corresponding volume controls 6-12 and 6-13 and selector switches 9-1 and 9-2, to the power amplifiers 7-9 and 7-10 for amplification. Then, the thus-amplified front left and right signals FL and FR are passed via the selector switches 10-1 and 10-2 to the speaker terminals 8-11 and 8-12 to be output therefrom. In this manner, 8.1-channel audio reproduction is performed in the first zone Zone1.

On the other hand, if the Zone-2 audio reproduction switch is turned on as determined at step S5 of FIG. 2, the zone enabling signal Z2ON is enabled at step S6, so that each of the selector switches 9-1, 9-2, 10-1 and 10-2 is caused to connect to the Z2 contact, at step S7. In this way, analog audio signals Z2L and Z2R, input to the input terminals 1-4 and 1-5, are sent, via the corresponding volume controls 6-8 and 6-9 and selector switches 9-1 and 9-2, to the power amplifiers 7-9 and 7-10 for amplification, and the thus-amplified signals are then passed via the selector switches 10-1 and 10-2 to the speaker terminals 8-7 and 8-8 to be output therefrom.

Also, in response to the enabling of the zone switching signal Z2ON, the switches 421d and 422d within the DSP 4d are each caused to connect to the Z2 contact. Thus, in order to compensate for reduction in the multichannel audio reproduction effect due to stoppage of supply, to the front speakers SP-FL and SP-FR of the first zone Zone1, of the front left and right signals FL and FR, sound field correction is performed on the main left and right signals L and R to be supplied to the first zone Zone1, at step S8.

In the fourth embodiment, the front left and right signals FL and FR are added to the main left and right signals L and R, respectively, in order to execute 8.1-channel multichannel audio reproduction using the main speakers SP-L and SP-R, rear speakers SP-RL and SP-RR, center speaker SP-C, rear center speaker SP-RC and subwoofer SP-SW.

Namely, the front left signal FL output from the sound processing section 402d is passed via the switch 421d to an adder 424d for addition to the main left signal L, while the front right signal FR output from the sound processing section 402d is passed via the switch 422d to an adder 426d for addition to the main right signal R.

The main left and right signals L and R, rear left and right signals RL and RR, center signal C, rear center signal RC and subwoofer signal LFE, having been subjected to the sound field correction in the above-described manner, are sent to the D/A converter 5d. The main left and right signals L and R, rear left and right signals RL and RR and subwoofer signal LFE, output from the D/A converter 5d, are processed in generally the same manner as in the first embodiment. The center signal C and rear center signal RC, output from the D/A converter 5d, are sent through the volume controls 6-5 and 6-6 to the power amplifiers 7-5 and 7-6 for amplification, and the thus-amplified center signal C and rear center signal RC are then output via the speaker terminals 8-5 and 8-6.

Note that respective gains of the main left and right signals L and R and front left and right signals FL and FR are set for the sound field correction such that the sound fields in the first zone Zone1 have desired characteristics.

With the above-described arrangements, the fourth embodiment provided with 8-channel built-in power amplifiers can achieve the same benefits as the first embodiment. In the fourth embodiment of FIG. 7, the volume controls 6-12 and 6-13 can be shared between the first zone Zone1 and the second zone Zone2, by providing the selector switches 9-1 and 9-2 between the D/A converter 5d and the volume controls 6-12 and 6-13 and controlling the values of the volume controls 6-12 and 6-13 via the control section 12a, in response to turning on/off of the Zone-2 audio reproduction switch, in generally the same manner as in the second embodiment. As a consequence, the fourth embodiment can achieve the same benefits as the second embodiment.

Whereas, in the above-described first to fourth embodiments, analog audio signals Z2L and Z2R are input to the audio reproduction apparatus as signals to be delivered to the second zone Zone2, the present invention is not so limited. For example, digital audio signals Z2L and Z2R may be input to the audio reproduction apparatus and converted into analog audio signals so as to be delivered to the second zone Zone2.

The sound field correction of the first zone Zone1 in each of the first to fourth embodiments may be carried out in any desired manner other than the above-described. Further, because separate power amplifiers are allocated to the second zone Zone2, if rear surround components can not be output from the rear speakers of the first zone Zone1, the sound field correction may be carried out by so-called virtual sound field processing such that the rear sound fields can be reproduced by the front speakers alone.

The present invention having been described above in relation to the first to fourth embodiments can be summarized as follows. Namely, according to the present invention, when the audio reproduction apparatus is in the first mode where no audio reproduction is to be executed in the second zone, a first audio signal of m channel is selected via the first selector switch and supplied to the power amplifier of the m channel, and the output of the power amplifier of the m channel is coupled, via the second selector switch, to a speaker terminal of the first zone. In this way, the maximum multichannel audio reproduction effect can be achieved in the first zone. Further, in the second mode, the DSP carries out sound field correction such that the sound fields in the first zone have desired characteristics, so that the present invention can appropriately compensate for reduction in the multichannel audio reproduction effect due to stoppage of supply, to the first zone, of the first audio signal of the m channel and thereby achieves a sufficient multichannel audio reproduction effect.

Further, in the present invention, a particular volume control is shared between sound volume adjustment of the first audio signal of the m channel and sound volume adjustment of the second audio signal of the m channel, and thus the number of the necessary components can be reduced significantly.

Furthermore, as a switchover takes place from the first mode to the second mode, a current value of the volume control of the m channel, having been adjusting the sound volume of the first audio signal, is stored as a volume value for the first zone, and a prestored volume value for the second zone is set in the volume control of the m channel. On the other hand, as a switchover takes place from the second mode to the first mode, a current value of the volume control of the m channel, having been adjusting the sound volume of the second audio signal, is stored as a volume value for the second zone, and a prestored volume value for the first zone is set in the volume control of the m channel. Such arrangements can eliminate the need for the user to re-set the volume control in response to switching of the mode and thereby enhance the convenience for the user (user friendliness).

### Fifth Embodiment

FIG. 9 is a block diagram showing a setup of an audio reproduction apparatus in accordance with a fifth embodiment of the present invention. The audio reproduction apparatus of FIG. 9 includes input terminals 1 (1-1, 1-2 and 1-3), an A/D converter 22, a DSP 3a, power amplifiers 14 (14-1, 14-2, 14-3, 14-4 and 14-5), speaker output terminals 5 (5-1, 5-2, 5-3, 5-4, 5-5, 5-6, and .5-7), main speaker changing switches 16 (16-1, 16-2, 16-3 and 16-4), a subwoofer output terminal 17, and a control section 18. For convenience of the following description, the main speaker changing switches 16-1 and 16-2 are referred to as “spA” switches, while the main speaker changing switches 16-3 and 16-4 are referred to as “spB” switches. In the instant embodiment, the control section 18 functions as a mode setting section for setting a place where main speakers of a B group are to be used. Further, the DSP 3a stops output or supply of surround signals when the output to main speakers of an A group is OFF (i.e., the spA switches are in an OFF state) and the output to main speakers of the B group is ON (i.e., the spB switches are in an ON state) and when a second zone ZoneB to be later described has been selected as a place where the B-group main speakers are to be positioned.

The embodiment of FIG. 9 is intended to perform 5.1-channel audio reproduction that is a typical example of the multichannel audio reproduction. When analog audio signals ALIN and ARIN of two channels are input to the input terminals 1-1 and 1-2, the A/D converter 22 converts the input analog audio signals ALIN and ARIN into digital audio signals. The thus-converted digital audio signals are passed to the DSP 3a, where the audio signals are subjected to sound field processing as may be necessary. However, a further description of these input signals is omitted because they are not multichannel audio inputs to be processed in accordance with the basic principles of the present invention. On the other hand, when a digital sound signal DIN, compression-coded by the Dolby Digital, DTS or AAC technique, is input to the input terminal 1-3, the DSP 3a decompression-decodes the input compression-coded digital sound signal DIN by means of an internal decoder (not shown), to thereby generate various analog audio signals, i.e. main left and right signals L and R, rear left and right signals RL and RR, center signal C and subwoofer signal LFE. When the DSP 3a is set to an OFF state (or downmix position), the main left and right signals L and R are output from the DSP 3a, but, when the DSP 3a is set to an ON state (or in a multichannel audio reproduction position), the main left and right signals L and R, rear left and right signals RL and RR, center signal C and subwoofer signal LFE are output from the DSP 3a.

For the fifth embodiment of FIG. 9, speakers are arranged in the first and second zones ZoneA and ZoneB in the same manner as shown in FIG. 21. The speaker output terminals 5-1, 5-2, 5-3, 5-4 and 5-5 are connected with main speakers SP-AL, SP-AR, rear speakers SP-RL, SP-RR and center speaker SP-C, respectively, in the first zone ZoneA, and the subwoofer output terminal 17 is connected with a subwoofer SP-SW provided with a built-in amplifier. Further, the speaker output terminals 5-6 and 5-7 are connected with main speakers SP-BL and SP-BR, respectively, in the second zone ZoneB.

The B-group main speakers may be positioned in either the first zone ZoneA or in the second zone ZoneB. Where the B-group main speakers are positioned in the second zone ZoneB, the user operates the audio reproduction apparatus to set a use mode of the B-group main speakers to “ZoneB”, and the control section 18 enables a mode switching signal MSEL.

Further, in the case where the B-group main speakers SP-BL and SP-BR are positioned in the first zone ZoneA and an audio comparison or the like is to be made between outputs from the A-group main speakers SP-AL and SP-AR and the B-group main speakers SP-BL and SP-BR, the use mode of the B-group main speakers is set to “MAIN”, and the control section 18 disenables the mode switching signal MSEL.

The following description will be made, assuming that the A-group main speakers SP-AL and SP-AR are positioned in the first zone ZoneA, the B-group main speakers SP-BL and SP-BR are positioned in the second zone ZoneB and the DSP 3a is in the ON state. In such a case, the spA and spB switches will take any one of four different combinations of ON/OFF states: the first one where the spA and spB switches are both ON, the second one where the spA switches are ON and the spB switches are OFF, the third one where the spA switches are OFF and the spB switches are ON; and the fourth one where the spA and spB switches are both OFF.

[In the case where the spA switches are ON and the spB switches are OFF]

When audio reproduction is to be executed using the A-group main speakers SP-AL and SP-AR positioned in the first zone ZoneA, the user depresses an A-group main speaker selecting switch (not shown). FIG. 10 is a flow chart showing operations performed by the audio reproduction apparatus of FIG. 9 as switching takes place between the A- and B-groups of the main speakers. If the A-group main speaker selecting switch has been depressed with a B-group main speaker selecting switch left undepressed (i.e., with a NO determination at step ST1 and YES determination at step ST2 of FIG. 10), the control section 18 enables an A-group main speaker selecting signal SSELA and disables a B-group main speaker selecting signal SSLEB, at step ST3.

As the A-group main speaker selecting signal SSELA is enabled, the A-group main speaker changing switches spA are turned on, and as the B-group main speaker selecting signal SSELB is disabled, the B-group main speaker changing switches spB are turned off (step ST4). Also, the DSP 3a outputs main left and right signals L and R, rear left and right signals RL and RR, center signal C and subwoofer signal LFE, at step ST5. The main left and right signals L, R, rear left and right signals RL, RR and center signal C, output from the DSP 3a, are amplified by the corresponding amplifiers 14-1, 14-2, 14-3, 14-4 and 14-5, and then output from the speaker output terminals 5-1, 5-2, 5-3, 5-4 and 5-5. Subwoofer signal LFE output from the subwoofer output terminal 17 is supplied to the subwoofer SP-SW provided with a built-in amplifier.

[In the case where the spA switches are OFF and the spB switches are ON]

When audio reproduction is to be executed in the second zone ZoneB, the user depresses the B-group main speaker selecting switch with the A-group main speaker selecting switch left undepressed. If the B-group main speaker selecting switch has been depressed with the A-group main speaker selecting switch left undepressed (i.e., with an YES determination at step ST1 and NO determination at step ST6 of FIG. 10), the control section 18 disables the A-group main speaker selecting signal SSELA and enables the B-group main speaker selecting signal SSLEB, at step ST7. As the A-group main speaker selecting signal SSELA is disabled like this, the A-group main speaker changing switches spA are turned off, and as the B-group main speaker selecting signal SSELB is enabled, the B-group main speaker changing switches spB are turned on (step ST8).

On the other hand, if the A-group main speaker selecting signal SSELA is invalid while the B-group main speaker selecting signal SSELB is valid (effective) and if the mode switching signal MSEL is valid (YES determination at step ST9), the DSP 3a stops output or supply of the individual surround signals, i.e. rear left and right signals RL and RR, center signal C and subwoofer signal LEF, at step ST10. Further, the DSP 3a imparts effect sounds to the main left and right signals L and R at step ST11. The main left and right signals L and R, having been imparted with the effect sounds, are amplified by the power amplifiers 14-1 and 14-2, respectively, and passed via the main speaker changing switches spB to the speaker output terminals 5-6 and 5-7, from which the main signals L and R are supplied to the B-group main speakers SP-BL and SP-BR.

The following paragraphs outline the concept of an effect sound impartment process performed on the main left and right signals L and R. To execute 5.1-channel multichannel audio reproduction via the main speakers SP-BL and SP-BR of two channels, there arises a need to allocate the rear left and right signals RL and RR, center signal C and subwoofer signal LFE to the main left and right signals L and R.

Namely, because it is only necessary that the center signal C, to be supplied to the center speaker SP-C, be localized between the main left and right signals L and R, the center signal C may be allocated and added to the main left and right signals L and R. Further, because sound image localization of the subwoofer signal LFE to be supplied to the subwoofer SP-SW does not matter so much, the subwoofer signal LFE may also be allocated and added to the main left and right signals L and R.

When the rear left and right signals RL and RR are to be output from the main speakers SP-BL and SP-BR and their sound images are to be localized at the positions of the rear speakers SP-RL and SP-RR, there arises a need to convert frequency characteristics and delay times of the audio signals into those of sounds that will be heard from behind the listening position (human listener). Namely, the user has empirically learned to presume directions and distances of sounds reaching the left and right ears on the basis of differences in their arrival times and frequency components; thus, in order to provide so-called virtual speakers, by which the rear left and right signals RL and RR are output from the main speakers SP-BL and SP-BR and their sound images are localized as if the sounds were reaching from behind the human listener, there is a need to process the rear left and right signals RL and RR so that the signals RL and RR have generally the same time differences and frequency components as when they are actually output from the rear speakers SP-RL and SP-RR, and then supply the thus-processed signals RL and RR to the main speakers SP-BL and SP-BR.

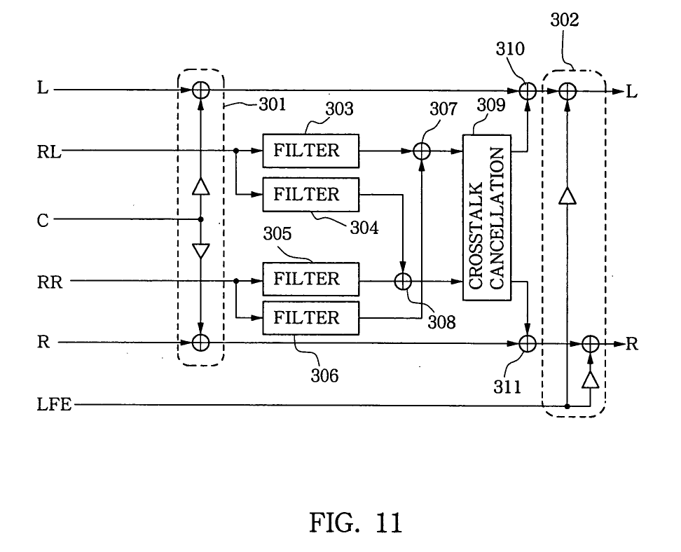

The following paragraphs describe details of the effect sound impartment process. FIG. 11 is a block diagram showing an example of the effect sound impartment process performed by the DSP 3a on the main left and right signals L and R. Note that FIG. 11 only diagramatically illustrates operations (functions) performed by the DSP 3a, not an actual structure of the DSP 3a. The center signal C is divided by an adder circuit 301, and the thus-divided signals are added to the main left and right signals L and R. Similarly, the subwoofer signal LFE is divided by an adder circuit 302, and the thus-divided signals are added to the main left and right signals L and R.

In a filter 303, there are preset filter coefficients for simulating, with a standard model of a user's head shape, a head-related transfer function, representative of a characteristic of an audio reaching the user's left year from the rear speaker SP-RL. Thus, the rear left signal RL is filtered in such a manner that the signal RL has generally the same time difference and frequency characteristic as when it is actually output from the rear speaker SP-RL to reach the user's left ear. Similarly, in a filter 304, there are preset filter coefficients for simulating, with the above-mentioned standard model, a head-related transfer function, representative of a characteristic of an audio reaching the user's right year from the rear speaker SP-RL. Thus, the rear signal RL is filtered in such a manner that the signal RL has generally the same time difference and frequency characteristic as when it is actually output from the rear speaker SP-RL to reach the user's right ear. Further, in a filter 305, there are preset filter coefficients for simulating, with the above-mentioned standard model, a head-related transfer function, representative of a characteristic of an audio reaching the user's right year from the rear speaker SP-RR. Thus, the rear signal RR is filtered in such a manner that the signal RR has generally the same time difference and frequency characteristic as when it is actually output from the rear speaker SP-RR to reach the user's right ear. Similarly, in a filter 306, there are preset filter coefficients for simulating, with the above-mentioned standard model, a head-related transfer function, representative of a characteristic of an audio reaching the user's left year from the rear speaker SP-RR. Thus, the rear signal RR is filtered in such a manner that the signal RR has generally the same time difference and frequency characteristic as when it is actually output from the rear speaker SP-RR to reach the user's left ear.

The rear left signal RL having been filtered by the filter 303 and the rear right signal RR having been filtered by the filter 306 are added by an adder 307 and then passed to a crosstalk cancellation circuit 309 for removal of an undesired crosstalk component, so that the signal having the crosstalk component removed therefrom is added to the main left signal L by an adder 310. The rear right signal RR having been filtered by the filter 305 and the rear signal RL having been filtered by the filter 304 are added by an adder 308 and then passed to the crosstalk cancellation circuit 309 for removal of an undesired crosstalk component, so that the signal having the crosstalk component removed therefrom is added to the main right signal R by an adder 311.

The DSP 3a outputs the main left and right signals L and R having been imparted with effect sounds in the above-described manner. The main left and right signals L and R output from the DSP 3a are supplied, via the corresponding 14-1 and 14-2, to the main speakers SP-BL and SP-BR.

As set forth above, the fifth embodiment of the present invention is arranged to stop the supply, to the first zone ZoneA, of the individual surround signals, i.e. rear left and right signals RL and RR, center signal C and subwoofer signal LEF, on condition that the B-group main speakers SP-BL and SP-BR are positioned in the second zone ZoneB, the use mode of the B-group main speakers is set to “ZoneB” and the output to the B-group main speakers is turned on with the output to the A-group main speakers set in the OFF state. Thus, the fifth embodiment can prevent unnecessary surround signals from being reproduced in the first zone ZoneA. Further, by imparting effect sounds to the main left and right signals L and R, the fifth embodiment can achieve realism (feeling of presence) in the multichannel audio reproduction, using the main speakers SP-BL and SP-BR of two channels positioned in the second zone ZoneB.

[In the case where the spA switches are ON and the spB switches are ON]

If the A-group and B-group main speaker selecting switches have both been depressed (i.e., with an YES determination at step ST1 and YES determination at step ST6 of FIG. 10), the control section 18 of the audio reproduction apparatus enables the A-group and B-group main speaker selecting signals SSELA and SSLEB, at step ST13. As the A-group and B-group main speaker selecting signals SSELA and SSLEB are disabled like this, the A-group and B-groups main speaker changing switches spA and spB are turned on at step ST14. The DSP 3a outputs the main left and right signals L and R, rear left and right signals RL and RR, center signal C and subwoofer signal LEF directly as they are, at step ST15. In this way, 5.1-channel audio reproduction is executed in the first zone ZoneA using the A-group main speakers SP-AL and SP-AR, rear speakers SP-RL and SP-RR, center speaker SP-C and subwoofer SP-SW, and simultaneously 2-channel audio reproduction is executed in the second zone ZoneB using the B-group main speakers SP-BL and SP-BR.

[In the case where the spA switches are OFF and the spB switches are OFF]

If neither the A-group main speaker selecting switches nor the B-group main speaker selecting switch has been depressed (i.e., with a NO determination at step ST1 and NO determination at step ST2 of FIG. 10), the control section 18 of the audio reproduction apparatus disables both of the A-group and B-group main speaker selecting signals SSELA and SSLEB, so that the main speaker changing switches spA and spB are turned off to output no audio.

The preceding paragraphs have described the case where the B-group main speakers are positioned in the second zone ZoneB. Needless to say, the B-group main speakers may be positioned in the first zone ZoneA together with the A-group main speakers. In such a case, the use mode of the B-group main speakers is set to “MAIN” as noted earlier. When the use mode of the B-group main speakers has been set to “MAIN”, the DSP 3a outputs the main left and right signals L and R, rear left and right signals RL and RR, center signal C and subwoofer signal LEF directly as they are, irrespective of the place where the B-group main speakers are positioned. Therefore, the operations performed by the audio reproduction apparatus when the A-group and B-group main speakers are used simultaneously are similar to the operations of steps ST13-ST15 above, except that the B-group main speakers are positioned in the first zone ZoneA.

When the use mode of the B-group main speakers has been set to “MAIN” and only the B-group main speaker selecting button has been depressed, a NO determination is made at step ST9 of FIG. 10, so that the main left and right signals L and R, rear left and right signals RL and RR, center signal C and subwoofer signal LEF are supplied to the main speakers SP-BL and SP-BR, rear speakers SP-RL and SP-RR, center speaker SP-C and subwoofer SP-SW, at step ST12.

### Sixth Embodiment

FIG. 12 is a block diagram showing an audio reproduction apparatus in accordance with a sixth embodiment of the present invention, where the same elements as in the embodiment of FIG. 9 are represented by the same reference characters as in FIG. 9. The sixth embodiment will be described below as an apparatus intended for 6.1-channel audio reproduction. On the basis of an input digital audio signal DIN, a DSP 3b of the apparatus generates various analog audio signals, i.e. main left and right signals L and R, rear left and right signals RL and RR, center signal C, subwoofer signal LFE and rear center signal RC. When the DSP 3b is in an OFF state (or downmix position), the main left and right signals L and R are output from the DSP 3b, but, when the DSP 3b is in an ON state, the main left and right signals L and R, rear left and right signals RL and RR, center signal C, subwoofer signal LFE and rear center signal RC are output from the DSP 3b.

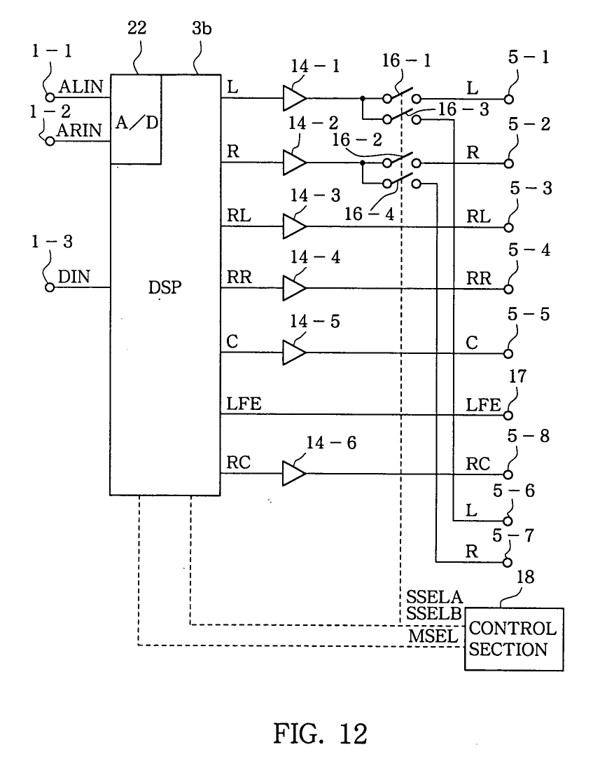

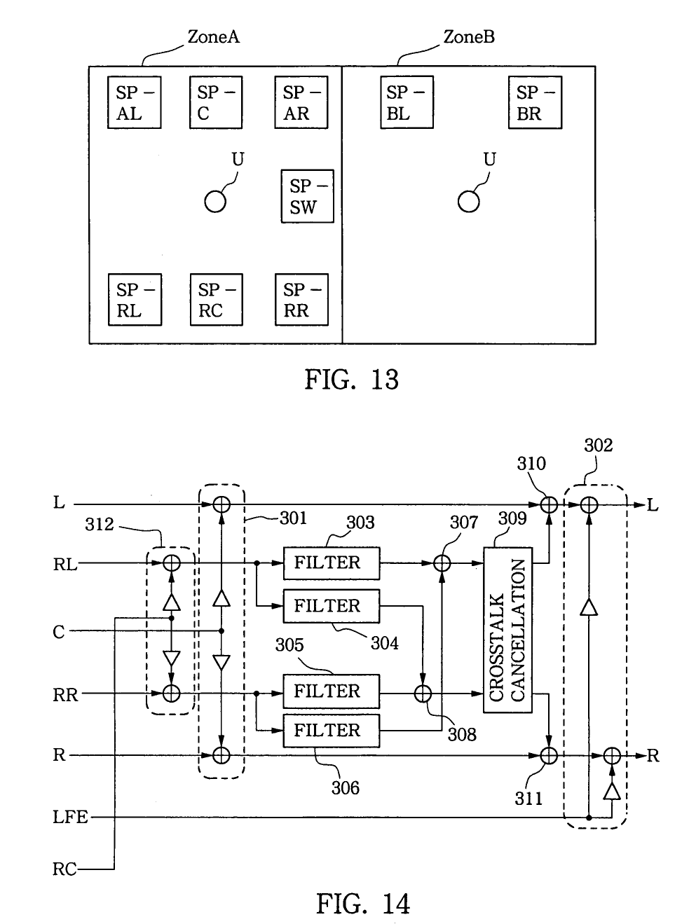

FIG. 13 shows arrangement of speakers in the first and second zones ZoneA and ZoneB employed in the audio reproduction apparatus of FIG. 12. The arrangement of FIG. 13 is similar to that shown in FIG. 21, except that a rear center speaker SP-RC is added to the speakers in the first zone ZoneA. The speaker output terminal 5-8 is connected with the rear center speaker SP-RC.

Operations performed by the audio reproduction apparatus of FIG. 12 as switching takes place between the groups of the main speakers are similar to those described above in relation to the fifth embodiment, and therefore they will be described, with reference to FIG. 10, on the assumption that the A-group main speakers SP-AL and SP-AR are positioned in the first zone ZoneA, the B-group main speakers SP-BL and SP-BR are positioned in the second zone ZoneB and the DSP 3b is in the ON state.

If the A-group main speaker selecting switch has been depressed with the B-group main speaker selecting switch left undepressed (i.e., with a NO determination at step ST1 and YES determination at step ST2 of FIG. 10), the control section 18 enables the A-group main speaker selecting signal SSELA and disables the B-group main speaker selecting signal SSLEB, at step ST3. Consequently, the A-group main speaker changing switches spA are turned on, and the B-group main speaker changing switches spB are turned off (step ST4). Also, the DSP 3b outputs main left and right signals L and R, rear left and right signals RL and RR, center signal C, subwoofer signal LFE and rear center signal RC, at step ST5. The main left and right signals L, R, rear left and right signals RL, RR and center signal C and subwoofer signal LFE, output from the DSP 3b, are processed in the same manner as described above in relation to the fifth embodiment. The rear center signal RC output from the DSP 3b is amplified by the corresponding amplifier 14-6 and then output from the speaker output terminal 5-8. In this way, the 6.1-channel audio reproduction is executed in the first zone ZoneA.

If the B-group main speaker selecting switch has been depressed with the A-group main speaker selecting switch left undepressed (i.e., with an YES determination at step ST1 and NO determination at step ST6 of FIG. 10), the control section 18 disables the A-group main speaker selecting signal SSELA and enables the B-group main speaker selecting signal SSLEB, at step ST7. Consequently, the A-group main speaker changing switches spA are turned off, and the B-group main speaker changing switches spB are turned on (step ST8). If the A-group main speaker selecting signal SSELA is invalid while the B-group main speaker selecting signal SSELB is valid and if the mode switching signal MSEL is valid (YES determination at step ST9), the DSP 3b stops output of the individual surround signals, i.e. rear left and right signals RL and RR, center signal C, subwoofer signal LEF and rear center signal RC, at step ST10, and the DSP 3b imparts effect sounds to the main left and right signals L and R by an effect sound impartment process at step ST11.

At that time, the effect sound impartment process may include, in addition to the operations as described above in relation to the fifth embodiment, operations for processing the rear center signal RC to have generally the same time difference and frequency characteristic as when the sound actually reaches the user from the rear center speaker SP-RC and thereby supplying the thus-processed signal RC to the main speakers SP-BL and SP-BR.

FIG. 14 is a block diagram showing an example of the effect sound impartment process performed by the DSP 3b on the main left and right signals L and R, where the same operations as in the example of FIG. 11 are depicted by the same reference characters. Because it is only necessary that the rear center signal RC be localized between the rear left and right signals RL and RR, the signal RC may be allocated and added to the rear left and right signals RL and RR before a filter process. Namely, the rear center signal RC is divided by an adder circuit 312, and the thus-divided signals are added to the rear left and right signals RL and RR before the filter process. The rear left and right signals RL and RR, center signal C and subwoofer signal LEF are processed in the same manner as in the fifth embodiment. The DSP 3b outputs the main left and right signals L and R having been imparted with effect sounds in the above-described manner. In this way, the sixth embodiment can achieve realism (feeling of presence) in the multichannel audio reproduction, using the main speakers SP-BL and SP-BR of two channels positioned in the second zone ZoneB.

Whereas the preceding paragraphs have described the sixth embodiment as using either one of the A-group and B-group main speakers, the A-group and B-group main speakers may be used simultaneously as in the fifth embodiment.

### Seventh Embodiment

FIG. 15 is a block diagram showing a setup of an audio reproduction apparatus in accordance with a seventh embodiment of the present invention, where the same elements as in the embodiment of FIG. 12 are represented by the same reference characters as in FIG. 12. The seventh embodiment will be described below as an apparatus intended for 8.1-channel audio reproduction. On the basis of an input digital audio signal DIN, a DSP 3c of the apparatus generates various analog audio signals, i.e. main left and right signals L and R, rear left and right signals RL and RR, center signal C, subwoofer signal LFE, rear center signal RC and front left and right signals FL and FR.

When the DSP 3c is in an OFF state (or downmix position), the main left and right signals L and R are output from the DSP 3c, but, when the DSP 3b is in an ON state, the main left and right signals L and R, rear left and right signals RL and RR, center signal C, subwoofer signal LFE, rear center signal RC and front left and right signals FL and FR are output from the DSP 3b.

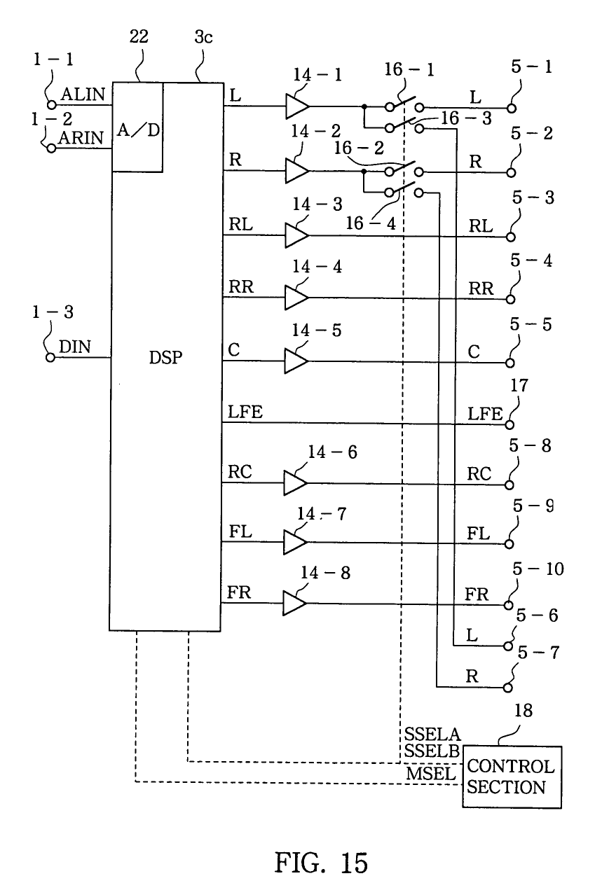

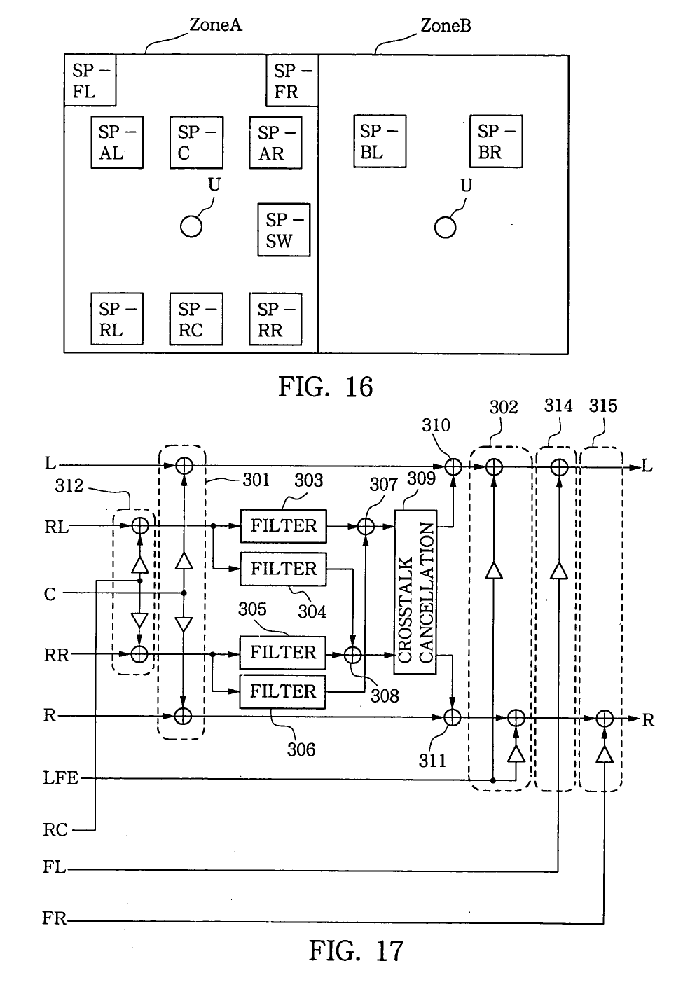

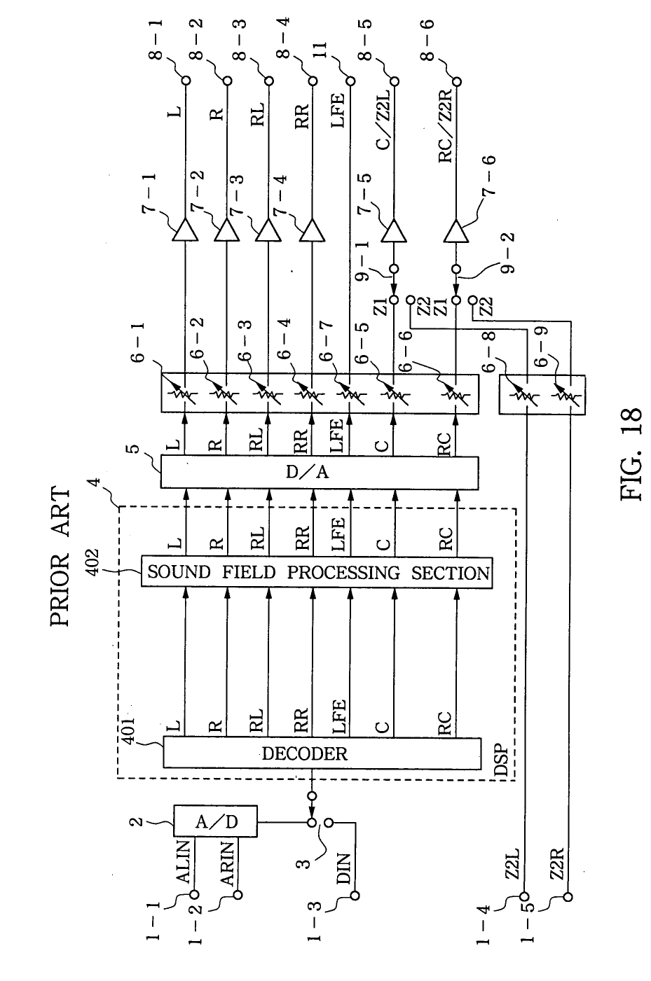

FIG. 16 shows arrangement of speakers in the first and second zones ZoneA and ZoneB employed in the audio reproduction apparatus of FIG. 15. The arrangement of FIG. 16 is similar to that shown in FIG. 13, except that front speakers SP-FL and SP-FR are added to the speakers in the first zone ZoneA of FIG. 13. The speaker output terminals 5-9 and 5-10 are connected with the front speakers SP-FL and SP-FR. In this case, because the A-group and B-group main speakers are positioned in the different zones, the mode switching signal MSEL is enabled.

Operations performed by the audio reproduction apparatus of FIG. 15 as switching takes place between the groups of the main speakers are similar to those described above in relation to the fifth embodiment, and therefore they will be described, with reference to FIG. 10, on the assumption that the A-group main speakers SP-AL and SP-AR are positioned in the first zone ZoneA, the B-group main speakers SP-BL and SP-BR are positioned in the second zone ZoneB and the DSP 3c is in the ON state.

If the A-group main speaker selecting switch has been depressed with the B-group main speaker selecting switch left undepressed (i.e., with a NO determination at step ST1 and YES determination at step ST2 of FIG. 10), the control section 18 enables the A-group main speaker selecting signal SSELA and disables the B-group main speaker selecting signal SSLEB, at step ST3. Consequently, the A-group main speaker changing switches spA are turned on, and the B-group main speaker changing switches spB are turned off (step ST4). The DSP 3c outputs main left and right signals L and R, rear left and right signals RL and RR, center signal C, subwoofer signal LFE, rear center signal RC and front left and right signals FL and FR, at step ST5. The main left and right signals L, R, rear left and right signals RL, RR, center signal C, subwoofer signal LFE and rear center signal RC, output from the DSP 3c, are processed in the same manner as in the sixth embodiment. The front left and right signals FL and FR output from the DSP 3c are amplified by the corresponding amplifiers 14-7 and 14-8 and then output from the speaker output terminals 5-9 and 5-10. In this way, the 8.1-channel audio reproduction is executed in the first zone ZoneA.

If, on the other hand, the B-group main speaker selecting switch has been depressed with the A-group main speaker selecting switch left undepressed (i.e., with an YES determination at step ST1 and NO determination at step ST6 of FIG. 10), the control section 18 disables the A-group main speaker selecting signal SSELA and enables the B-group main speaker selecting signal SSLEB, at step ST7. Consequently, the A-group main speaker changing switches spA are turned off, and the B-group main speaker changing switches spB are turned on (step ST8). If the A-group main speaker selecting signal SSELA is invalid and the B-group main speaker selecting signal SSELB is valid and if the mode switching signal MSEL is valid (YES determination at step ST9), the DSP 3c stops output of the individual surround signals, i.e. rear left and right signals RL and RR, center signal C, subwoofer signal LEF, rear center signal RC and front left and right signals FL and FR, at step ST10. Further, the DSP 3c imparts effect sounds to the main left and right signals L and R by an effect sound impartment process, at step ST11.

At that time, the effect sound impartment process may include, in addition to the operations as described above in relation to the sixth embodiment, operations for adding the front left and right signals FL and FR to the main left and right signals L and R. FIG. 17 is a block diagram showing an example of the effect sound impartment process performed by the DSP 3c on the main left and right signals L and R, where the same operations as in the example of FIG. 14 are depicted by the same reference characters.

The front left signal FL is added to the main signal L by an adder 314, while the front right signal FR is added to the main signal R by an adder 315. The DSP 3c outputs the main left and right signals L and R having been imparted with effect sounds in the above-described manner. In this way, the seventh embodiment can achieve realism in the multichannel audio reproduction, using the main speakers SP-BL and SP-BR of two channels in the second zone ZoneB.

Whereas the preceding paragraphs have described the seventh embodiment as using either one of the A-group and B-group main speakers, the A-group and B-group main speakers may be used simultaneously as in the fifth embodiment.

The present invention having been described above in relation to the fifth to seventh embodiments can be summarized as follows.

The audio reproduction apparatus of the present invention is provided with the mode setting section that can selectively set usage of either one of the first mode where speakers connected to first speaker output terminals and speakers connected to second speaker output terminals are both positioned and used in the first zone, and the second mode where the speakers connected to the first speaker output terminals are positioned and used in the first zone and the speakers connected to the second speaker output terminals are positioned and used in the second zone. Thus, the present invention can achieve optimal audio reproduction corresponding to the usage of the speakers connected to the second speaker output terminal. When the output to the first speaker output terminals is off while the output to the second speaker output terminals is on and the second mode is selected by the mode setting section, the digital signal processor stops outputting the surround signals. With such arrangements, the present invention can prevent the unnecessary surround signals from being reproduced in the first zone.

Further, when the output to the first speaker output terminals is off while the output to the second speaker output terminals is on and the second mode is selected by the mode setting section, the digital signal processor imparts effect sounds to the main signals. With such arrangements, the present invention can achieve a so-called virtual speaker that allows sound images of rear signals to be localized in rear of a human listener, thereby accomplishing realism of multichannel audio reproduction using main speakers of two channels.

The present invention relates to the subject matter of Japanese Patent Application Nos. 2002-210528 and 2002-215588 filed on Jul. 19, 2002 and Jul. 24, 2002, the disclosure of which is expressly incorporated herein by reference in its entirety.

What is claimed is:

1. An audio reproduction apparatus having: a first mode for performing multichannel audio reproduction to deliver first audio signals of n (n is an integral number in a range of n≧4) channels from power amplifiers of the n channels to a first zone; and a second mode for performing multizone audio reproduction to deliver, from said power amplifier of m channel (m is an integral number in a range of 1≦m<n) not used for the multichannel audio reproduction, a second audio signal of the m channel to said second zone while performing multichannel audio reproduction to deliver said first audio signals of (n−m) channels from said power amplifiers of the (n−m) channels to said first zone, said audio reproduction apparatus comprising:
a digital signal processor that processes said first audio signals of the n channels and outputs the processed first audio signals to said power amplifiers of the n channels;
a first selector switch connected to an input of said power amplifier of the m channel, wherein, in said first mode, said first selector switch selects said first audio signal of the m channel corresponding to said power amplifier of the m channel from among said first audio channels of the n channels outputted by said digital signal processor, while, in said second mode, said first selector switch selects said second audio signal of the m channel; and
a second selector switch connected to an output of said power amplifier of the m channel, wherein, in said first mode, said second selector switch couples the output of said power amplifier of the m channel to a speaker terminal provided for said first zone, while, in said second mode, said second selector switch couples the output of said power amplifier of the m channel to a speaker terminal provided for said second zone,
wherein, in said second mode, said digital signal processor performs sound field correction on at least a portion of said first audio signals of the (n−m) channels so that a sound field of said first zone has a desired characteristic.

2. An audio reproduction apparatus as claimed in claim 1 wherein a particular volume control is shared between sound volume adjustment of said first audio signal of the m channel and sound volume adjustment of said second audio signal of the m channel.

3. An audio reproduction apparatus as claimed in claim 2 which further comprises a control section that, as switching takes place from said first mode to said second mode, stores a current value of said volume control of the m channel, having been adjusting a sound volume of said first audio signal, as a volume value for said first zone and sets a prestored volume value for said second zone in the volume control of the m channel, but, as switching takes place from said second mode to said first mode, stores a current value of said volume control of the m channel, having been adjusting a sound volume of said second audio signal, as a volume value for said second zone and sets a prestored volume value for said first zone in the volume control of the m channel.

4. An audio reproduction apparatus for supplying main signals, to be reproduced in front of a human listener, to main speakers and supplying surround signals to surround speakers so as to give the human listener a surround feeling, said audio reproduction apparatus comprising:
a digital signal processor that outputs the surround signals;
a power amplifier that amplifies the main signals;
an output switching member operable to perform ON/OFF control on output from said power amplifier to first speaker output terminals and output from said power amplifier to second speaker output terminals independently of each other; and
a mode setting section that can select either one of a first mode where speakers connected to said first speaker output terminals and speakers connected to said second speaker output terminals are both positioned and used in a first zone, and a second mode where the speakers connected to said first speaker output terminals are positioned and used in said first zone and the speakers connected to said second speaker output terminals are positioned and used in a second zone,
wherein, when the output to said first speaker output terminals is off while the output to said second speaker output terminals is on and said second mode is selected by said mode setting section, said digital signal processor stops outputting the surround signals.

5. An audio reproduction apparatus as claimed in claim 4 wherein, when the output to said first speaker output terminals is off while the output to said second speaker output terminals is on and said second mode is selected by said mode setting section, said digital signal processor imparts an effect sound to the main signals.
